(19) United States
(12) Patent Application Publication
(10) Pub. No.: US 2025/0014645 A1
(43) Pub. Date: Jan. 9, 2025

(54) NONVOLATILE MEMORY DEVICES AND MEMORY PACKAGES INCLUDING THE SAME

(71) Applicant: Samsung Electronics Co., Ltd., Suwon-si (KR)

(72) Inventors: Minsu Kim, Suwon-si (KR); Hongsoo Jeon, Suwon-si (KR)

(21) Appl. No.: 18/443,463

(22) Filed: Feb. 16, 2024

(30) Foreign Application Priority Data
Jul. 3, 2023 (KR) 10-2023-0085764

(51) Int. Cl. G11C 16/08; G11C 5/06; G11C 16/04; H10B 41/10; H10B 41/27; H10B 41/35; H10B 41/41; H10B 43/10; H10B 43/27; H10B 43/35; H10B 43/40

(52) U.S. Cl. CPC G11C 16/08; G11C 5/063; G11C 16/0483; H10B 41/10; H10B 41/27; H10B 41/35; H10B 41/41; H10B 43/10; H10B 43/27; H10B 43/35; H10B 43/40

(57) ABSTRACT

A nonvolatile memory device includes first and second semiconductor layers and pass transistors. The first semiconductor layer includes wordlines that extend in a first direction and bitlines that extend in a second direction, and further includes a first substrate and a memory cell array. The memory cell array is on the first substrate and connected to the wordlines and the bitlines. The second semiconductor layer is arranged with respect to the first semiconductor layer in a third direction, and includes a second substrate and a peripheral circuit. The peripheral circuit is on the second substrate and controls the memory cell array. The pass transistors are connected to the wordlines and control an electrical connection between the memory cell array and the peripheral circuit. A first part of the pass transistors are in the first semiconductor layer, and a second part of the pass transistors are in the second semiconductor layer.

### CROSS-REFERENCE TO RELATED APPLICATION

This application claims priority under 35 USC § 119 to Korean Patent Application No. 10-2023-0085764, filed on Jul. 3, 2023, in the Korean Intellectual Property Office (KIPO), and the entire contents of the above-identified application are incorporated by reference herein.

### BACKGROUND

### 1. Technical Field

Aspects of the present disclosure relate generally to semiconductor integrated circuits, and more particularly to nonvolatile memory devices and memory packages including the nonvolatile memory devices.

### 2. Description of the Related Art

Vertical memory devices, also known as three-dimensional (3D) memory devices, are memory devices that include a plurality of memory cells stacked repeatedly on a surface of a substrate. These memory devices are able to have a relatively high storage capacity within a relatively small structure. For example, in a vertical memory device, a channel may protrude or may be extended vertically from the surface of the substrate, and gate lines and insulation layers surrounding the vertical channel may be repeatedly stacked.

However, the reduction of the size of the vertical memory device is limited because the memory device should still include a peripheral circuit for driving a memory cell array and a wiring structure to electrically connect the memory cell array with the peripheral circuit. Accordingly, there exists a demand for memory devices having a high degree of integration and excellent electrical characteristics.

### SUMMARY

Some aspects of the present disclosure provide a nonvolatile memory device having a reduced size and/or a reduced manufacturing cost.

Some aspects of the present disclosure provide a memory package including the nonvolatile memory device.

According to some example embodiments, a nonvolatile memory device may include a first semiconductor layer, a second semiconductor layer and a plurality of pass transistors. The first semiconductor layer includes a plurality of wordlines that extend in a first direction and a plurality of bitlines that extend in a second direction that intersects the first direction, and further includes a first substrate and a memory cell array. The memory cell array is on the first substrate and connected to the plurality of wordlines and the plurality of bitlines. The second semiconductor layer is arranged with respect to the first semiconductor layer in a third direction perpendicular to both the first direction and the second direction, and includes a second substrate and a peripheral circuit. The peripheral circuit is on the second substrate and controls the memory cell array. The plurality of pass transistors are connected to the plurality of wordlines and control an electrical connection between the memory cell array and the peripheral circuit. A first part of the plurality of pass transistors are in the first semiconductor layer, and a second part of the plurality of pass transistors are in the second semiconductor layer.

According to some example embodiments, a nonvolatile memory device includes a first semiconductor layer, a second semiconductor layer, a third semiconductor layer and a plurality of pass transistors. The first semiconductor layer includes a plurality of wordlines that extend in a first direction and a plurality of bitlines that extend in a second direction that intersects the first direction, and further includes a first substrate and a memory cell array. The memory cell array is on the first substrate and connected to the plurality of wordlines and the plurality of bitlines. The second semiconductor layer is arranged with respect to the first semiconductor layer in a third direction perpendicular to both the first direction and the second direction, and includes a second substrate and a first peripheral circuit. The first peripheral circuit is on the second substrate, and controls the memory cell array. The third semiconductor layer is arranged with respect to the first semiconductor layer in the third direction, and includes a third substrate and a second peripheral circuit. The second peripheral circuit is on the third substrate, and controls the memory cell array. The plurality of pass transistors are connected to the plurality of wordlines and control an electrical connection between the memory cell array and the first and second peripheral circuits. A first part of the plurality of pass transistors are in the second semiconductor layer, and a second part of the plurality of pass transistors are in the third semiconductor layer.

According to example embodiments, a memory package includes a base substrate and a plurality of memory chips stacked on the base substrate. Each of the plurality of memory chips includes a first semiconductor layer, a second semiconductor layer and a plurality of pass transistors. The first semiconductor layer includes a plurality of wordlines that extend in a first direction and a plurality of bitlines that extend in a second direction that intersects the first direction, and further includes a first substrate and a memory cell array. The memory cell array is on the first substrate and connected to the plurality of wordlines and the plurality of bitlines. The second semiconductor layer is arranged with respect to the first semiconductor layer in a third direction perpendicular to both the first direction and the second direction, and includes a second substrate and a peripheral circuit. The peripheral circuit is on the second substrate and controls the memory cell array. The plurality of pass transistors are connected to the plurality of wordlines and control an electrical connection between the memory cell array and the peripheral circuit. A first part of the plurality of pass transistors are in the first semiconductor layer, and a second part of the plurality of pass transistors are in the second semiconductor layer.

According to some example embodiments, a nonvolatile memory device includes a first semiconductor layer, a second semiconductor, a plurality of pass transistors and a plurality of drivers. The first semiconductor layer includes a plurality of wordlines that extend in a first direction and a plurality of bitlines that extend in a second direction that intersects the first direction, and further includes a first substrate and a memory cell array. The memory cell array is on the first substrate and connected to the plurality of wordlines and the plurality of bitlines. The second semiconductor layer is arranged with respect to the first semiconductor layer in a third direction perpendicular to both the first direction and the second direction, and includes a second substrate and a peripheral circuit. The peripheral circuit is on the second substrate and controls the memory cell array. The plurality of pass transistors are connected to the plurality of wordlines and control an electrical connection between the memory cell array and the peripheral circuit. The plurality of drivers control switching operations of the plurality of pass transistors. The memory cell array includes a core region and an extension region. The core region includes a plurality of memory cells. The extension region is adjacent to a first side of the core region and includes a plurality of wordline contacts for electrical connections between the plurality of wordlines and the plurality of pass transistors. The plurality of wordlines include first wordlines and second wordlines. The plurality of pass transistors include first pass transistors connected to the first wordlines, and second pass transistors connected to the second wordlines. The plurality of drivers include first drivers control switching operations of the first pass transistors, and second drivers control switching operations of the second pass transistors. The plurality of wordline contacts includes first wordline contacts electrically connect the first wordlines with the first pass transistors, and second wordline contacts electrically connect the second wordlines with the second pass transistors. The first pass transistors and the first drivers are in the first substrate of the first semiconductor layer, and the second pass transistors and the second drivers are in the second substrate of the second semiconductor layer. The first wordline contacts and the second wordline contacts are in the extension region of the first semiconductor layer.

In the nonvolatile memory device and the memory package according to example embodiments, the BVNAND structure in which the peripheral circuit and the memory cell array are stacked may be adopted, and thus the nonvolatile memory device may have a relatively small size.

In addition, the pass transistors for controlling the electrical connection between the memory cell array and the peripheral circuit may be separated and/or distributed in the different semiconductor layers. Thus, an area in which where the pass transistors are placed within one semiconductor layer may be reduced, and the wiring complexity for connecting the pass transistors with the wordlines may be reduced. Accordingly, the circuit area may be reduced, the manufacturing cost may be reduced, and thus the nonvolatile memory device may be efficiently manufactured.

### BRIEF DESCRIPTION OF THE DRAWINGS

Illustrative, non-limiting example embodiments will be more clearly understood from the following detailed description taken in conjunction with the accompanying drawings.

FIG. 1 is a perspective view of a nonvolatile memory device according to some example embodiments.

FIG. 2 is a cross-sectional view of a nonvolatile memory device according to some example embodiments.

FIG. 3 is a block diagram illustrating a nonvolatile memory device according to some example embodiments.

FIG. 4 is a perspective view of an example of a memory block included in a memory cell array of a nonvolatile memory device of FIG. 3.

FIG. 5 is a circuit diagram illustrating an equivalent circuit of a memory block described with reference to FIG. 4.

FIG. 6 is a block diagram illustrating an example of an address decoder included in a nonvolatile memory device of FIG. 3.

FIGS. 7A, 7B and 7C are cross-sectional views for describing a channel hole included in a nonvolatile memory device according to some example embodiments.

FIGS. 8A, 8B and 8C are diagrams for describing a core region and an extension region that are included in a nonvolatile memory device according to some example embodiments.

FIG. 9 is a cross-sectional view of an example of a nonvolatile memory device of FIG. 2.

FIG. 10 is a cross-sectional view of an example of a wordline contact included in a nonvolatile memory device of FIG. 9.

FIGS. 11 and 12 are cross-sectional views of examples of a nonvolatile memory device of FIG. 2.

FIGS. 13A and 13B are perspective views of a nonvolatile memory device according to some example embodiments.

FIGS. 14A and 14B are cross-sectional views of examples of a nonvolatile memory device of FIG. 2.

FIGS. 15A, 15B, 15C, 15D and 15E are diagrams illustrating a nonvolatile memory device according to some example embodiments.

FIGS. 16A, 16B, 16C and 16D are diagrams illustrating a nonvolatile memory device according to some example embodiments.

FIGS. 17A and 17B are cross-sectional views of a memory package according to some example embodiments.

FIG. 18 is a block diagram illustrating an electronic system including a nonvolatile memory device according to some example embodiments.

FIG. 19 is a cross-sectional view of a memory device according to some example embodiments.

FIG. 20 is a diagram illustrating a manufacturing process of a memory device according to some example embodiments.

### DETAILED DESCRIPTION OF THE EMBODIMENTS

Various examples of embodiments will be described more fully with reference to the accompanying drawings, in which some examples of embodiments are shown. The present disclosure may, however, be embodied in many different forms and should not be construed as limited in any way to the embodiments set forth herein. Like reference numerals refer to like elements throughout this application.

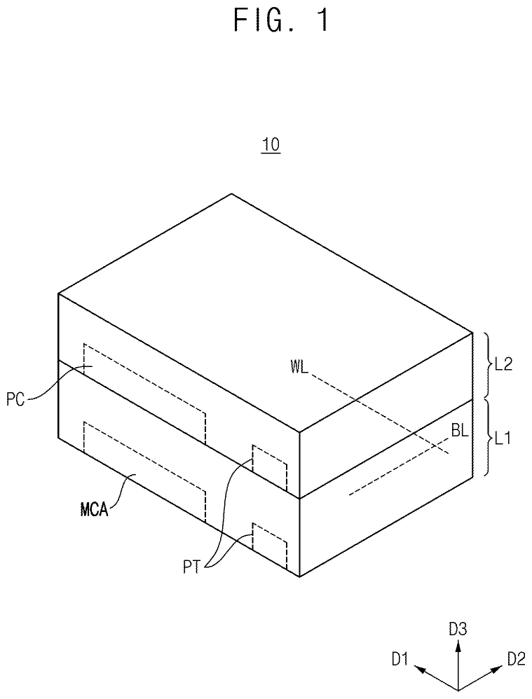

FIG. 1 is a perspective view of a nonvolatile memory device according to some example embodiments.

In FIG. 1, two directions that are each parallel or substantially parallel to a first surface (e.g., a top surface) of a substrate and crossing each other may be referred to as a first direction D1 (e.g., a X-axis direction) and a second direction D2 (e.g., a Y-axis direction). In addition, a direction vertical or substantially vertical to the first surface of the substrate may be referred to as a third direction D3 (e.g., a Z-axis direction). For example, the first and second directions D1 and D2 may be perpendicular or substantially perpendicular to each other. In addition, the third direction D3 may be perpendicular or substantially perpendicular to both the first and second directions D1 and D2. Further, a direction indicated by an arrow in the figures and a reverse direction thereof are considered as the same direction. The definition of the first, second and third directions D1, D2 and D3 are same in the subsequent figures.

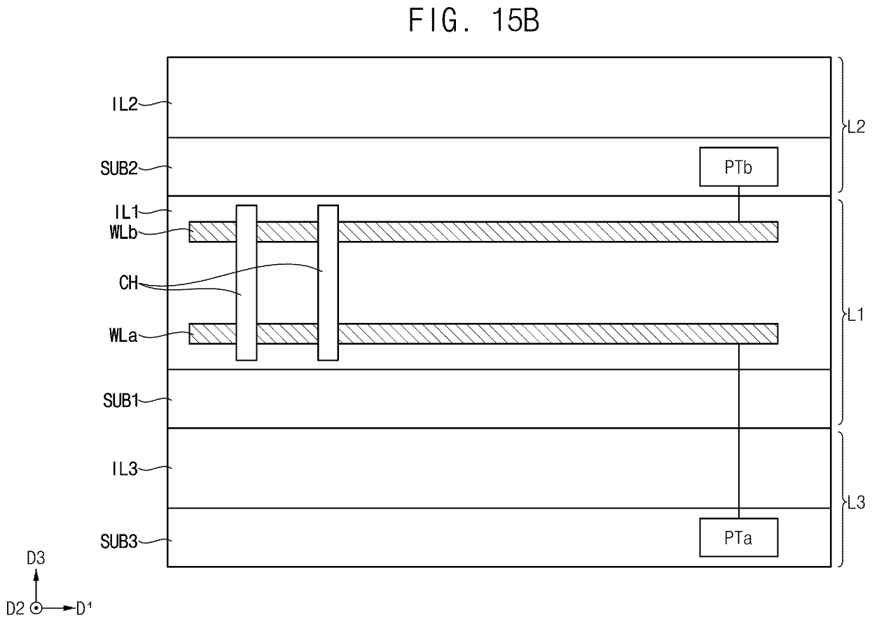

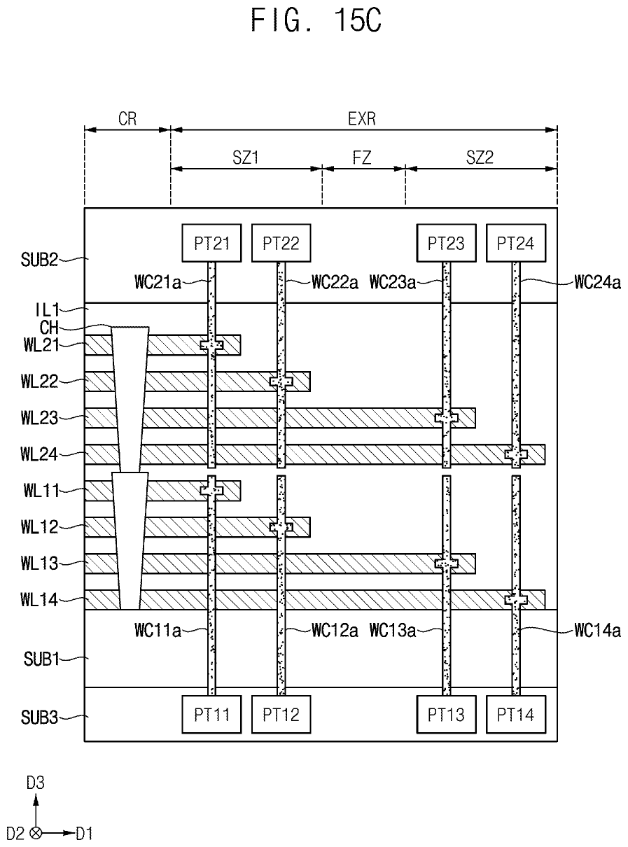

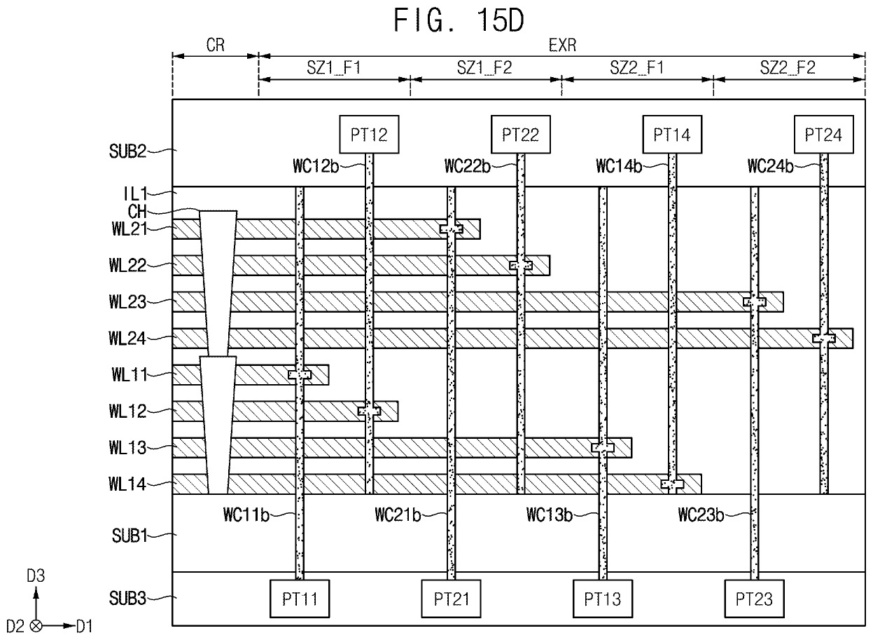

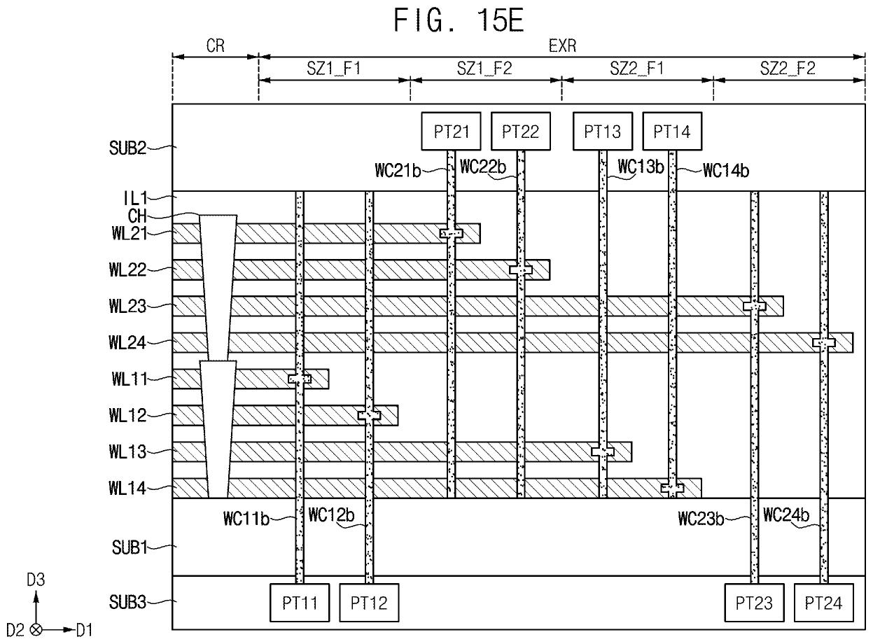

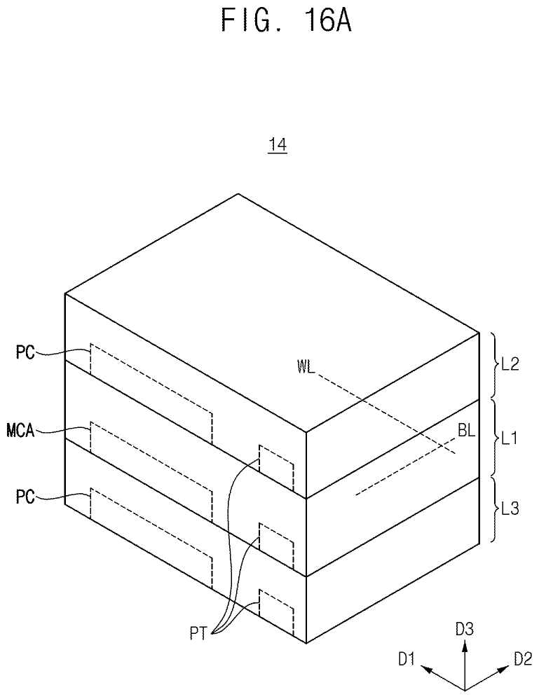

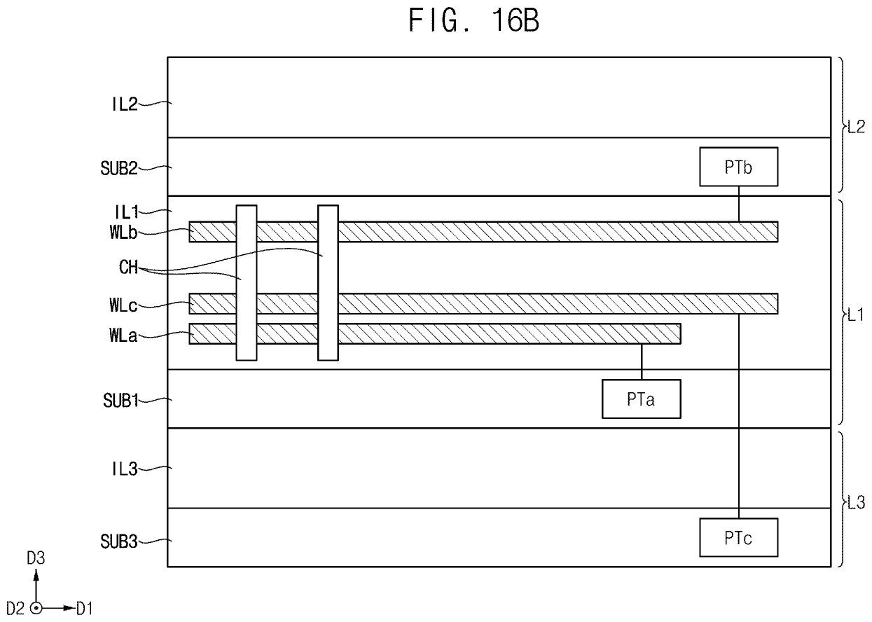

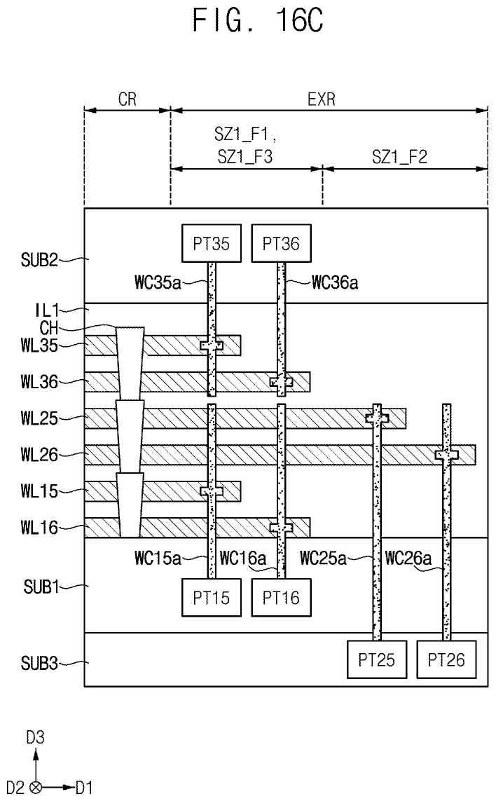

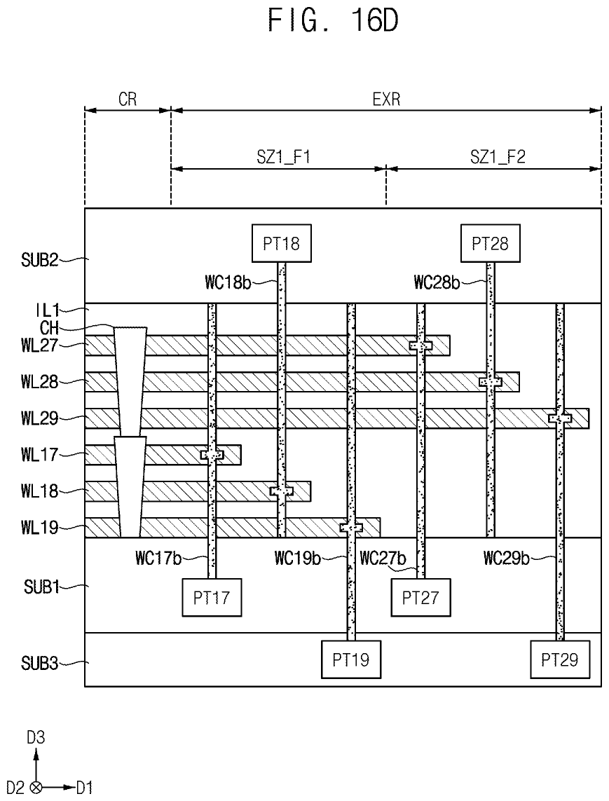

Referring to FIG. 1, a nonvolatile memory device 10 includes a first semiconductor layer L1 and a second semiconductor layer L2. The first semiconductor layer L1 and the second semiconductor layer L2 may be stacked in the third direction D3. For example, the first semiconductor layer L1 may be under (e.g., directly beneath or indirectly beneath) the second semiconductor layer L2 in the third direction D3, and the second semiconductor layer L2 may be stacked on the first semiconductor layer L1 in the third direction D3. However, example embodiments are not limited thereto. For example, the nonvolatile memory device 10 may be turned over during the manufacturing process, and thus the first semiconductor layer L1 may be stacked on the second semiconductor layer L2 in the third direction D3. In some example embodiments, as will be described with reference to FIGS. 15A and 16A, three or more semiconductor layers may be stacked in the third direction D3.

The first semiconductor layer L1 may include a plurality of wordlines WL, a plurality of bitlines and a memory cell array MCA. Thus, the first semiconductor layer L1 may be referred to as a memory cell region (MCR).

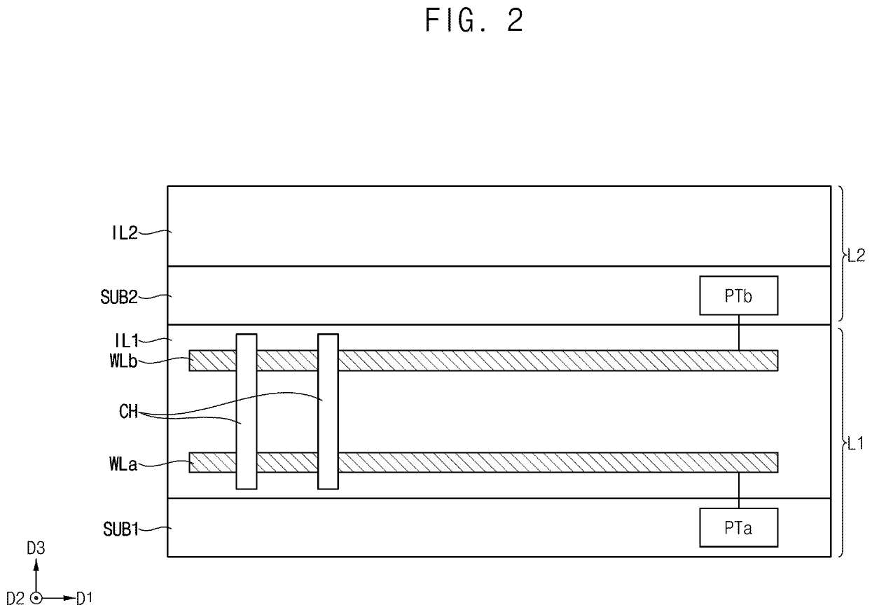

For example, as will be described with reference to FIG. 2, the first semiconductor layer L1 may include a first substrate, and the plurality of wordlines WL, the plurality of bitlines BL and the memory cell array MCA may be arranged and/or formed on the first substrate. For example, each of the plurality of wordlines WL may extend in the first direction D1, the plurality of wordlines WL may be arranged or spaced apart from each other along the second direction D2, and the plurality of wordlines WL may be stacked in the third direction D3. For example, each of the plurality of bitlines BL may extend in the second direction D2, and the plurality of bitlines BL may be arranged or spaced apart from each other along the first direction D1. For example, the memory cell array MCA may be connected to the plurality of wordlines WL and the plurality of bitlines BL.

The second semiconductor layer L2 may include a peripheral circuit PC that controls the memory cell array MCA. Thus, the second semiconductor layer L2 may be referred to as a peripheral circuit region (PCR).

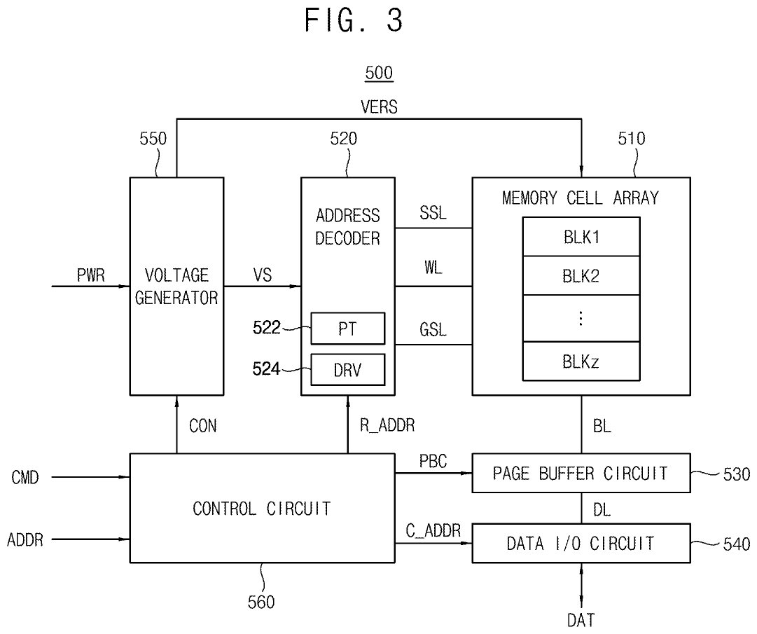

For example, as will be described with reference to FIG. 2, the second semiconductor layer L2 may include a second substrate, and the peripheral circuit PC may be arranged and/or formed on the second substrate. For example, as will be described with reference to FIG. 3, the peripheral circuit PC may include a control circuit, a page buffer circuit, and/or the like.

Although not illustrated in detail, the first semiconductor layer L1 may include patterns for electrically connecting the memory cell array MCA (e.g., the plurality of wordlines WL and the plurality of bitlines BL) with the circuits formed in the second semiconductor layer L2.

The nonvolatile memory device 10 may include a plurality of pass transistors PT. The plurality of pass transistors PT may be connected to the plurality of wordlines WL, and may control an electrical connection between the memory cell array MCA and the peripheral circuit PC. For example, some (e.g., a first part) of the plurality of pass transistors PT may be arranged and/or formed in the first semiconductor layer L1, and the others (e.g., a second part) of the plurality of pass transistors PT may be arranged and/or formed in the second semiconductor layer L2.

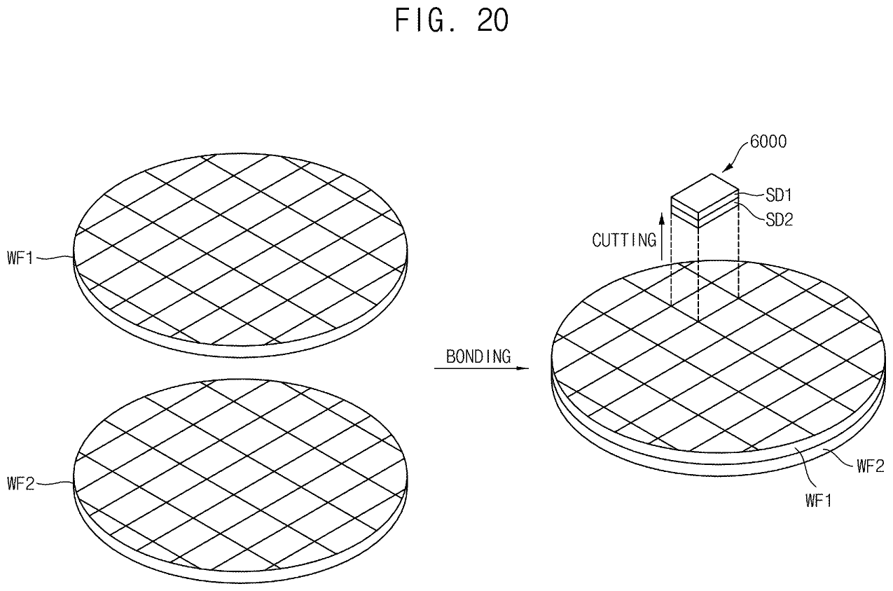

The nonvolatile memory device 10 according to some example embodiments may have or adopt a structure in which the peripheral circuit PC and the memory cell array MCA are stacked, e.g., a bonding vertical NAND (BVNAND) structure in which the peripheral circuit PC and the memory cell array MCA are disposed or arranged in the third direction D3. Accordingly, the nonvolatile memory device 10 may have a relatively small size. For example, the first semiconductor layer L1 may include first metal pads, the second semiconductor layer L2 may include second metal pads, and the first semiconductor layer L1 and the second semiconductor layer L2 may be manufactured on separate wafers. The first and second metal pads may be connected by a bonding method, and thus the first and second semiconductor layers L1 and L2 may be electrically connected in the third direction D3. The BVNAND structure will be described in greater detail with reference to FIG. 19.

However, example embodiments are not limited thereto, and the nonvolatile memory device 10 may have or adopt a cell over periphery (COP) structure in which the peripheral circuit PC is formed below and then the memory cell array MCA is stacked on the peripheral circuit PC in a single manufacturing process.

In addition, in the nonvolatile memory device 10 according to example embodiments, the plurality of pass transistors PT may be separated and/or distributed in the first and second semiconductor layers L1 and L2. For example, some of the pass transistors PT may be formed in the first semiconductor layer L1 and the others of the pass transistors PT may be formed in the second semiconductor layer L2, rather than forming all of the pass transistors PT in one of the first and second semiconductor layers L1 and L2. Thus, an area in which where the pass transistors PT are placed within one semiconductor layer may be reduced, and the wiring complexity for connecting the pass transistors PT with the wordlines WL may be reduced. Accordingly, the circuit area may be reduced, the manufacturing cost may be reduced, and thus the nonvolatile memory device 10 may be manufactured more efficiently.

FIG. 2 is a cross-sectional view of a nonvolatile memory device according to some example embodiments.

Referring to FIG. 2, a first semiconductor layer L1 may include a first substrate SUB1, first and second wordlines WLa and WLb, channels (or vertical channels or pillars) CH, a first pass transistor PTa, and a first insulating layer IL1. A second semiconductor layer L2 may include a second substrate SUB2, a second pass transistor PTb, and a second insulating layer IL2.

The first substrate SUB1 may be a supporting layer that supports components of the first semiconductor layer L1, and the second substrate SUB2 may be a supporting layer that supports components of the second semiconductor layer L2. For example, each of the first and second substrates SUB1 and SUB2 may be a silicon substrate and may be referred to as a base substrate. The first insulating layer IL1 may cover the components of the first semiconductor layer L1, and the second insulating layer IL2 may cover the components of the second semiconductor layer L2.

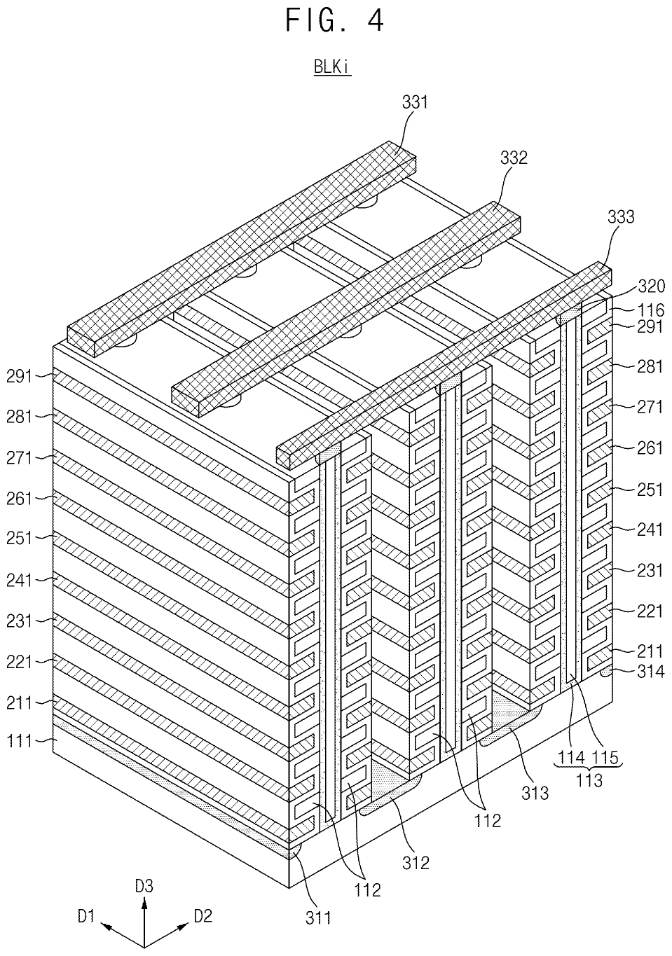

The wordlines WLa and WLb may be stacked on the first substrate SUB1 in the third direction D3. The channels CH may penetrate the wordlines WLa and WLb, and may extend in a direction (e.g., the third direction D3) perpendicular to the top surface of the first substrate SUB1. A memory cell array MCA including a plurality of memory cells may be formed in the first semiconductor layer L1 by the wordlines WLa and WLb and the channels CH. More detailed configurations of the wordlines WLa and WLb and the channels CH will be described later with reference to FIGS. 4, 7A, 7B, 7C, 8B and 8C.

The first pass transistor PTa may be formed in or on the first substrate SUB1, and may be connected to the first wordline WLa. The second pass transistor PTb may be formed in or on the second substrate SUB2, and may be and connected to the second wordline WLb.

The first and second pass transistors PTa and PTb may perform substantially the same operation, but may be formed on different substrates SUB1 and SUB2. In some example embodiments, the first and second pass transistors PTa and PTb may be manufactured to have different physical characteristics (e.g., channel length, etc.) in different substrates SUB1 and SUB2. In some example embodiments, at least one of widths and lengths of the first pass transistor PTa in the first semiconductor layer L1 and the second pass transistor PTb in the second semiconductor layer L2 may be different from each other.

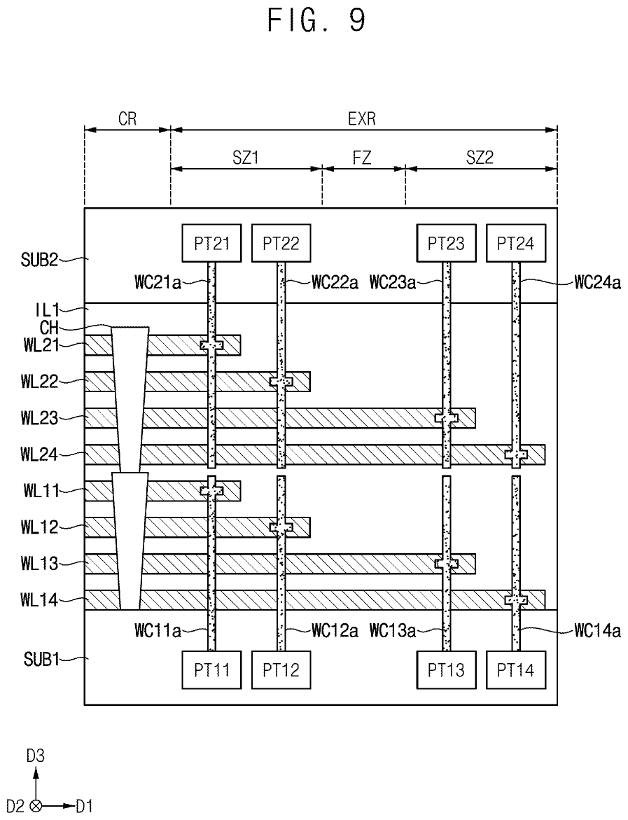

For convenience of illustration, FIG. 2 illustrates the nonvolatile memory device including only one first wordline WLa, one first pass transistor PTa, one second wordline WLb and one second pass transistor PTb. However, example embodiments are not limited thereto, and the nonvolatile memory device may include a plurality of first wordlines, a plurality of first pass transistors, a plurality of second wordlines and a plurality of second pass transistors. More detailed configurations of the wordlines and the pass transistors will be described with reference to FIGS. 9, 11, 12, 14A, 14B, 15C, 15D, 15E, 16C and 16D.

Although not illustrated in detail in FIG. 2, the peripheral circuit PC and various circuits may be formed in the second semiconductor layer L2 by forming semiconductor elements (e.g., transistors) and patterns for wiring the semiconductor elements on the second substrate SUB2 of the second semiconductor layer L2.

FIG. 3 is a block diagram illustrating a nonvolatile memory device according to some example embodiments.

Referring to FIG. 3, a nonvolatile memory device 500 may include a memory cell array 510, an address decoder 520, a page buffer circuit 530, a data input/output (I/O) circuit 540, a voltage generator 550 and a control circuit 560.

The nonvolatile memory device 500 may have the above-described BVNAND structure. In some example embodiments, the memory cell array 510 may be formed in the first semiconductor layer L1, and at least a part of the address decoder 520, the page buffer circuit 530, the data I/O circuit 540, the voltage generator 550 and the control circuit 560 may be formed in the second semiconductor layer L2.

The memory cell array 510 may be connected to the address decoder 520 via a plurality of string selection lines SSL, a plurality of wordlines WL and a plurality of ground selection lines GSL. The memory cell array 510 may be further connected to the page buffer circuit 530 via a plurality of bitlines BL. The memory cell array 510 may include a plurality of memory cells (e.g., a plurality of nonvolatile memory cells) that are connected to the plurality of wordlines WL and the plurality of bitlines BL. The memory cell array 510 may be divided into a plurality of memory blocks BLK1, BLK2, . . . , BLKz (with z being any positive integer), with each of the plurality of memory blocks BLK1, BLK2, . . . , BLKz including memory cells. In addition, each of the plurality of memory blocks BLK1, BLK2, . . . , BLKz may be divided into a plurality of pages.

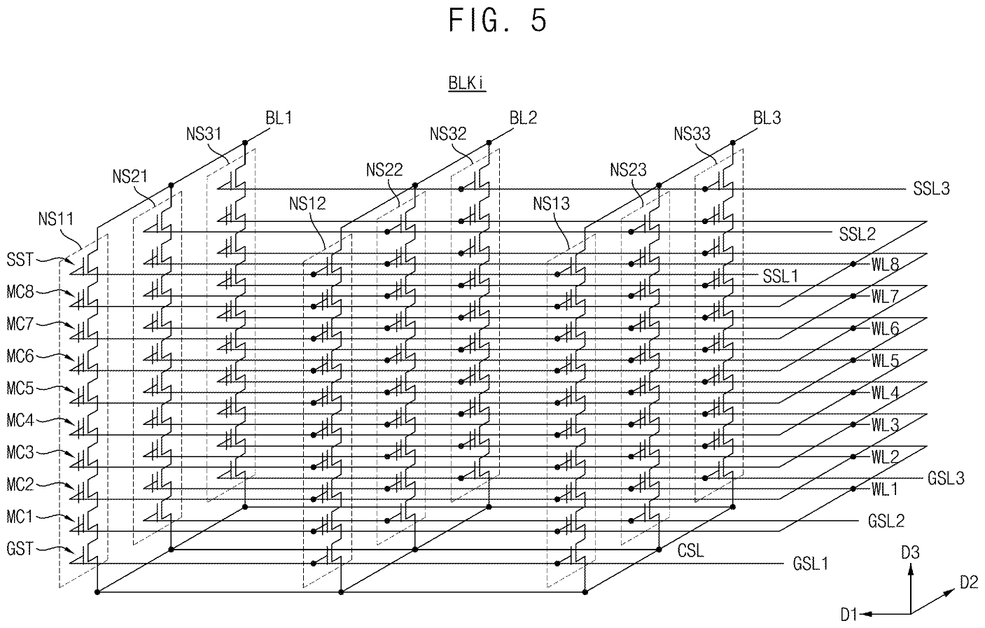

In some example embodiments, as will be described in greater detail with reference to FIGS. 4 and 5, the memory cell array 510 may be a three-dimensional memory cell array, which may be formed on a substrate in a three-dimensional structure (or a vertical structure). In this example, the memory cell array 510 may include a plurality of cell strings (e.g., a plurality of vertical NAND strings) that are vertically oriented such that at least one memory cell is located over another memory cell.

The control circuit 560 may receive a command CMD and an address ADDR from outside the nonvolatile memory device 500 (e.g., from a host device and/or a memory controller), and the control circuit 560 may be configured to control erasure, programming and read operations of the nonvolatile memory device 500 based on the command CMD and the address ADDR. An erasure operation may include performing a sequence of erase loops, and a program operation may include performing a sequence of program loops. Each program loop may include a program operation and a program verification operation. Each erase loop may include an erase operation and an erase verification operation. The read operation may include a normal read operation and data recover read operation.

In some example embodiments, the control circuit 560 may generate control signals CON, which may be used for controlling the voltage generator 550, and the control circuit 560 may generate control signal PBC, which may be used for controlling the page buffer circuit 530, based on the command CMD. The control circuit 560 may generate a row address R_ADDR and a column address C_ADDR based on the address ADDR. The control circuit 560 may provide the row address R_ADDR to the address decoder 520 and may provide the column address C_ADDR to the data I/O circuit 540.

The address decoder 520 may be connected to the memory cell array 510 via the plurality of string selection lines SSL, the plurality of wordlines WL and the plurality of ground selection lines GSL. In some example embodiments, in the data erase/write/read operations, the address decoder 520 may determine at least one of the plurality of wordlines WL as a selected wordline, may determine at least one of the plurality of string selection lines SSL as a selected string selection line, and may determine at least one of the plurality of ground selection lines GSL as a selected ground selection line, based on the row address R_ADDR.

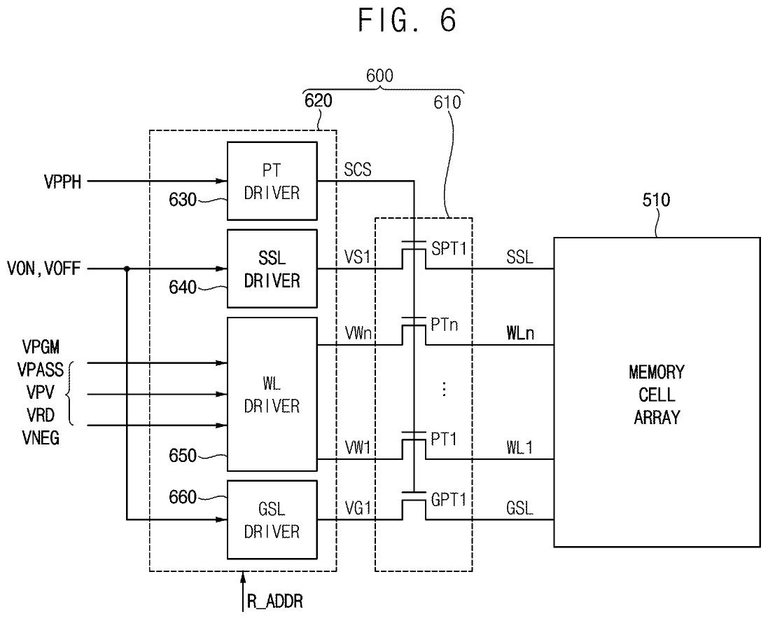

The address decoder 520 may include a plurality of pass transistors (PT) 522 and a plurality of drivers (DRV) 524. More detailed configurations of the plurality of pass transistors 522 and the plurality of drivers 524 will be described with reference to FIG. 6.

The voltage generator 550 may generate voltages VS that may be used for an operation of the nonvolatile memory device 500 based on a power PWR and the control signals CON. The voltages VS may be applied to the plurality of string selection lines SSL, the plurality of wordlines WL and the plurality of ground selection lines GSL via the address decoder 520. In addition, the voltage generator 550 may generate an erase voltage VERS that is used for the data erase operation based on the power PWR and the control signals CON.

The page buffer circuit 530 may be connected to the memory cell array 510 via the plurality of bitlines BL. The page buffer circuit 530 may include a plurality of page buffers. The page buffer circuit 530 may store data DAT to be programmed into the memory cell array 510 or may read data DAT sensed from the memory cell array 510. In other words, the page buffer circuit 530 may operate as a write driver and/or as a sensing amplifier according to an operation mode of the nonvolatile memory device 500.

The data I/O circuit 540 may be connected to the page buffer circuit 530 via data lines DL. The data I/O circuit 540 may provide the data DAT from an outside of the nonvolatile memory device 500 to the memory cell array 510 via the page buffer circuit 530 or may provide the data DAT from the memory cell array 510 to the outside of the nonvolatile memory device 500, based on the column address C_ADDR.

FIG. 4 is a perspective view of an example of a memory block BLKi included in a memory cell array of a nonvolatile memory device of FIG. 3.

Referring to FIG. 4, a memory block BLKi may include a plurality of cell strings (e.g., a plurality of vertical NAND strings) which may be formed on a substrate in a three-dimensional structure (or a vertical structure). The memory block BLKi includes structures extending along the first, second and third directions D1, D2 and D3.

A substrate 111 (e.g., the upper substrate of the first semiconductor layer L1) may be provided. In some example embodiments, the substrate 111 may have a well of a first type of charge carrier impurity (e.g., a first conductivity type) therein. In some example embodiments, the substrate 111 may have a p-well formed by implanting a group 3 (III) element such as boron (B). In particular, the substrate 111 may have a pocket p-well provided within an n-well. In some example embodiments, the substrate 111 has a p-type well (or a p-type pocket well). However, the conductive type of the substrate 111 is not limited to p-type.

A plurality of doping regions 311, 312, 313 and 314 arranged along the second direction D2 are provided in/on the substrate 111. These plurality of doping regions 311 to 314 may have a second type of charge carrier impurity (e.g., a second conductivity type) different from the first type of the substrate 111. In some example embodiments, the first to fourth doping regions 311 to 314 may have n-type. However, the conductive type of the first to fourth doping regions 311 to 314 is not limited to n-type.

A plurality of insulation materials 112 that extend along the first direction D1 are sequentially provided in the third direction D3 on a region of the substrate 111 between the first and second doping regions 311 and 312. In some example embodiments, the plurality of insulation materials 112 are provided in the third direction D3, and are spaced apart by a specific distance. In some example embodiments, the insulation materials 112 may include an insulation material such as an oxide layer.

A plurality of pillars 113 that penetrate or extend though the insulation materials in the third direction D3 are sequentially provided and spaced apart along the first direction D1 on a region of the substrate 111 between the first and second doping regions 311 and 312. In some example embodiments, the plurality of pillars 113 may penetrate the insulation materials 112 and may contact the substrate 111.

In some example embodiments, each pillar 113 may include a plurality of materials. In some example embodiments, a channel layer 114 of each pillar 113 may include a silicon material having a first conductivity type. In some example embodiments, the channel layer 114 of each pillar 113 may include a silicon material having the same conductivity type as the substrate 111. In some example embodiments, the channel layer 114 of each pillar 113 includes p-type silicon. However, the channel layer 114 of each pillar 113 is not limited to the p-type silicon.

An internal material 115 of each pillar 113 includes an insulation material. In some example embodiments, the internal material 115 of each pillar 113 may include an insulation material such as a silicon oxide. In some examples, the internal material 115 of each pillar 113 may include an air gap. The term “air” as discussed herein, may refer to atmospheric air, or other gases that may be present during the manufacturing process.

An insulation layer 116 may be provided along the exposed surfaces of the insulation materials 112, the pillars 113, and the substrate 111, on a region between the first and second doping regions 311 and 312. In some example embodiments, the insulation layer 116 provided on surfaces of the insulation material 112 may be interposed between pillars 113 and a plurality of stacked first conductive materials 211, 221, 231, 241, 251, 261, 271, 281 and 291, as illustrated. In some examples, the insulation layer 116 may not be provided between and may be absent from between the first conductive materials 211 to 291 corresponding to ground selection lines GSL (e.g., 211) and string selection lines SSL (e.g., 291). In this example, the ground selection lines GSL are the lowermost ones of the stack of first conductive materials 211 to 291 and the string selection lines SSL are the uppermost ones of the stack of first conductive materials 211 to 291.

The plurality of first conductive materials 211 to 291 may be provided on surfaces of the insulation layer 116, in a region between the first and second doping regions 311 and 312. In some example embodiments, the first conductive material 211 extending along the first direction D1 may be provided between the insulation material 112 adjacent to the substrate 111 and the substrate 111. In greater detail, the first conductive material 211 extending along the first direction D1 is provided between the insulation layer 116 at the bottom of the insulation material 112 adjacent to the substrate 111 and the substrate 111.

A first conductive material extending along the first direction D1 may be provided between the insulation layer 116 at the top of the specific insulation material among the insulation materials 112 and the insulation layer 116 at the bottom of a specific insulation material among the insulation materials 112. In some example embodiments, a plurality of first conductive materials 221 to 281 extending along the first direction D1 may be provided between the insulation materials 112 and it may be understood that the insulation layer 116 is provided between the insulation materials 112 and the first conductive materials 221 to 281. The first conductive materials 211 to 291 may be formed of a conductive metal, but in other embodiments the first conductive materials 211 to 291 may include a conductive material such as a polysilicon.

The same structures as those on the first and second doping regions 311 and 312 may be provided in a region between the second and third doping regions 312 and 313. In the region between the second and third doping regions 312 and 313, a plurality of insulation materials 112 are provided, which extend along the first direction D1. And, a plurality of pillars 113 may be provided that are arranged sequentially along the first direction D1 and penetrate or extend the plurality of insulation materials 112 along the third direction D3. An insulation layer 116 may be provided on the exposed surfaces of the plurality of insulation materials 112 and the plurality of pillars 113, and a plurality of first conductive materials 211 to 291 may extend along the first direction D1. Similarly, the same structures as those on the first and second doping regions 311 and 312 may be provided in a region between the third and fourth doping regions 313 and 314.

A plurality of drain regions may be are provided on the plurality of pillars 113, respectively. The drain regions 320 may include silicon materials doped with a second type of charge carrier impurity. In some example embodiments, the drain regions 320 may include silicon materials doped with an n-type dopant. In some example embodiments, the drain regions 320 include n-type silicon materials. However, the drain regions 320 are not limited to n-type silicon materials.

On the drain regions, a plurality of second conductive materials 331, 332 and 333 are provided, which extend along the second direction D2. The second conductive materials 331 to 333 may be arranged along the first direction D1, being spaced apart from each other by a specific distance. The second conductive materials 331 to 333 are respectively connected to the drain regions 320 in a corresponding region. The drain regions 320 and the second conductive material 333 extending along the second direction D2 may be connected through each contact plug. Each contact plug may be, in some example embodiments, a conductive plug formed of a conductive material such as a metal. The second conductive materials 331 to 333 may include metal materials. The second conductive materials 331 to 333 may include conductive materials such as a polysilicon.

In the example of FIG. 4, the first conductive materials 211 to 291 may be used to form the wordlines WL, the string selection lines SSL and the ground selection lines GSL. In some example embodiments, the first conductive materials 221 to 281 may be used to form the wordlines WL, where conductive materials belonging to the same layer may be interconnected. The second conductive materials 331 to 333 may be used to form the bitlines BL. The number of layers of the first conductive materials 211 to 291 may be changed variously according to process and control techniques.

FIG. 5 is a circuit diagram illustrating an equivalent circuit of a memory block described with reference to FIG. 4.

A memory block BLKi of FIG. 5 may be formed on a substrate in a three-dimensional structure (or a vertical structure). In some example embodiments, a plurality of NAND strings included in the memory block BLKi may be formed in a direction perpendicular to the substrate.

Referring to FIG. 5, the memory block BLKi may include a plurality of NAND strings NS11, NS12, NS13, NS21, NS22, NS23, NS31, NS32 and NS33 connected between bitlines BL1, BL2 and BL3 and a common source line CSL. Each of the NAND strings NS11 to NS33 may include a string selection transistor SST, a plurality of memory cells MC1, MC2, MC3, MC4, MC5, MC6, MC7 and MC8, and a ground selection transistor GST. In some example embodiments, the bitlines BL1 to BL3 may correspond to the second conductive materials 331 to 333 in FIG. 4, and the common source line CSL may be formed by interconnecting the first to fourth doping regions 311 to 314 in FIG. 4.

Each string selection transistor SST may be connected to a corresponding string selection line (one of SSL1, SSL2 and SSL3). The plurality of memory cells MC1 to MC8 may be connected to corresponding wordlines WL1, WL2, WL3, WL4, WL5, WL6, WL7 and WL8, respectively. Each ground selection transistor GST may be connected to a corresponding ground selection line (one of GSL1, GSL2 and GSL3). Each string selection transistor SST may be connected to a corresponding bitline (e.g., one of BL1 to BL3), and each ground selection transistor GST may be connected to the common source line CSL. In the example of FIG. 5, some of the string selection transistors SST are connected to the same bitline (e.g., one of BL1 to BL3) to connect corresponding NAND strings to the same bitline up appropriate selection via selection voltages applied to the appropriate sting selection lines SSL1 to SSL3 and ground selection lines GSL1 to GSL3.

The cell strings connected in common to one bitline may form one column, and the cell strings connected to one string selection line may form one row. In some example embodiments, the cell strings NS11, NS21 and NS31 connected to the first bitline BL1 may correspond to a first column, and the cell strings NS11, NS12 and NS13 connected to the first string selection line SSL1 may form a first row.

Wordlines (e.g., WL1) having the same height may be commonly connected, and the ground selection lines GSL1 to GSL3 and the string selection lines SSL1 to SSL3 may be separated. Memory cells located at the same semiconductor layer share a wordline. Cell strings in the same row share a string selection line. The common source line CSL is connected in common to all of cell strings.

In FIG. 5, the memory block BLKi is illustrated to be connected to eight wordlines WL1 to WL8 and three bitlines BL1 to BL3, and each of the NAND strings NS11 to NS33 is illustrated to include eight memory cells MC1 to MC8. However, the present disclosure is not limited thereto. In some example embodiments, each memory block may be connected to any number of wordlines and bitlines, and each NAND string may include any number of memory cells.

A three-dimensional vertical array structure may include vertical NAND strings that are vertically oriented such that at least one memory cell is located over another memory cell. The at least one memory cell may comprise a charge trap layer. The following patent documents, which are hereby incorporated by reference in their entirety, describe suitable configurations for a memory cell array including a 3D vertical array structure, in which the three-dimensional memory array is configured as a plurality of levels, with wordlines and/or bitlines shared between levels: U.S. Pat. Nos. 7,679,133; 8,553,466; 8,654,587; 8,559,235; and US Pat. Pub. No. 2011/0233648.

Although the memory cell array included in the nonvolatile memory device according to some example embodiments is described based on a NAND flash memory device, the nonvolatile memory device according to some example embodiments may be any nonvolatile memory device, e.g., a phase-change random access memory (PRAM), a resistive random access memory (RRAM), a nano floating gate memory (NFGM), a polymer random access memory (PoRAM), a magnetic random access memory (MRAM), a ferroelectric random access memory (FRAM), a thyristor random access memory (TRAM), and so on.

FIG. 6 is a block diagram illustrating an example of an address decoder included in a nonvolatile memory device of FIG. 3.

Referring to FIG. 6, an address decoder 600 may be connected to the memory cell array 510 through a string selection line SSL, wordlines WL1, . . . , WLn, and a ground selection line GSL, and may include a pass switch circuit 610 and a driver circuit 620. The address decoder 600 may be referred to as a row decoder, a wordline decoder, or the like.

The pass switch circuit 610 may include a plurality of pass transistors SPT1, PT1, . . . , PTn, and GPT1. For example, the plurality of pass transistors SPT1, PT1 to PTn and GPT1 may include a string pass transistor SPT1 connected to the string selection line SSL, wordline pass transistors PT1 to PTn connected to the wordlines WL1 to WLn, and a ground pass transistor GPT1 connected to the ground selection line GSL.

The driver circuit 620 may control switching operations of the plurality of pass transistors SPT1, PT1 to PTn and GPT1, and may control operations of supplying voltages VS1, VW1, . . . , VWn and VG1 to the memory cell array 510 through the plurality of pass transistors SPT1, PT1 to PTn and GPT1. The driver circuit 620 may include a pass transistor driver 630, a string selection line driver 640, a wordline driver 650 and a ground selection line driver 660.

The pass transistor driver 630 may generate a plurality of switching control signals SCS based on a high-voltage VPPH provided from a voltage generator (e.g., the voltage generator 550 in FIG. 3). The plurality of switching control signals SCS may be applied to gate electrodes of the plurality of pass transistors SPT1, PT1 to PTn and GPT1. The switching operations of the plurality of pass transistors SPT1, PT1 to PTn and GPT1 may be controlled in response to the plurality of switching control signals SCS. The timing at which the voltages VS1, VW1 to VWn and VG1 are applied to the memory cell array 510 may be controlled by the switching operations of the plurality of pass transistors SPT1, PT1 to PTn and GPT1.

The plurality of pass transistors SPT1, PT1 to PTn and GPT1 may be implemented such that the string selection line SSL, the wordlines WL1 to WLn, and the ground selection line GSL are electrically connected to the string selection line driver 640, the wordline driver 650 and the ground selection line driver 660, respectively, in response to activations of the plurality of switching control signals SCS. For example, the plurality of switching control signals SCS may be generated based on the high-voltage VPPH and may have a voltage level corresponding to the high-voltage VPPH, and thus the plurality of pass transistors SPT1, PT1 to PTn and GPT1 may include a high-voltage transistor capable of enduring the high-voltage.

The string selection line driver 640 may output one of an on-voltage VON and an off-voltage VOFF provided from the voltage generator as a string selection voltage VS. When the string pass transistor SPT1 is turned on, the string selection voltage VS1 may be applied to the memory cell array 510 through the string selection line SSL. When the string pass transistor SPT1 is turned on, the string selection voltage VS1 may be applied to the memory cell array 510 through the string selection line SSL. For example, during a program operation, the string selection line driver 640 may supply the string selection voltage VS1 so as to turn on all string selection transistors in a selected memory block.

The wordline driver 650 may output one of a program voltage VPGM, a pass voltage VPASS, a verification voltage VPV, a read voltage VRD and a negative voltage VNEG provided from the voltage generator to a respective one of the wordlines WL1 to WLn, according to an operation of a nonvolatile memory device (e.g., the nonvolatile memory device 500 of FIG. 3). When one of the wordline pass transistors PT1 to PTn are turned on, a respective one of wordline voltages VW1 to VWn may be provided to the memory cell array 510 through a respective one of the wordlines WL1 to WLn.

The ground selection line driver 660 may output one of the on-voltage VON and the off-voltage VOFF provided from the voltage generator as a ground selection voltage GS1. When the ground pass transistor GPT1 is turned on, the ground selection voltage GS1 may be applied to the memory cell array 510 through the ground selection line GSL.

In some example embodiments, each of the pass transistor driver 630, the string selection line driver 640, the wordline driver 650, and the ground selection line driver 660 may include a plurality of sub-drivers that control a part or portion of the memory cell array 510. In some example embodiments, the address decoder 600 may operate based on the row address R_ADDR.

In some example embodiments, the pass transistors PT1 to PTn connected to the wordlines WL1 to WLn may be the pass transistors PT, PTa and PTb according to example embodiments described with reference to FIGS. 1 and 2. For example, the pass transistors PT1 to PTn may be separately provided in the first and second semiconductor layers L1 and L2. For example, among the pass transistors PT1 to PTn, at least one of widths and lengths of pass transistors in the first semiconductor layer L1 and pass transistors in the second semiconductor layer L2 may be different from each other.

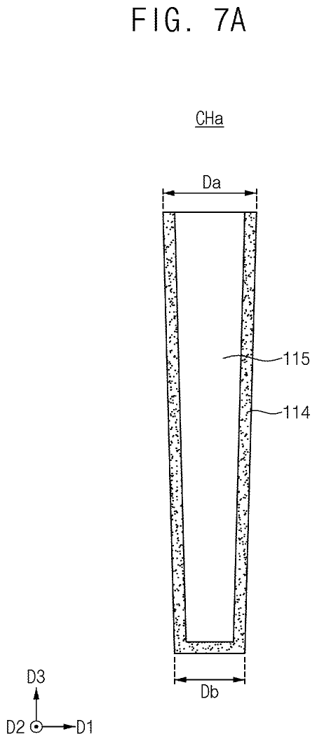

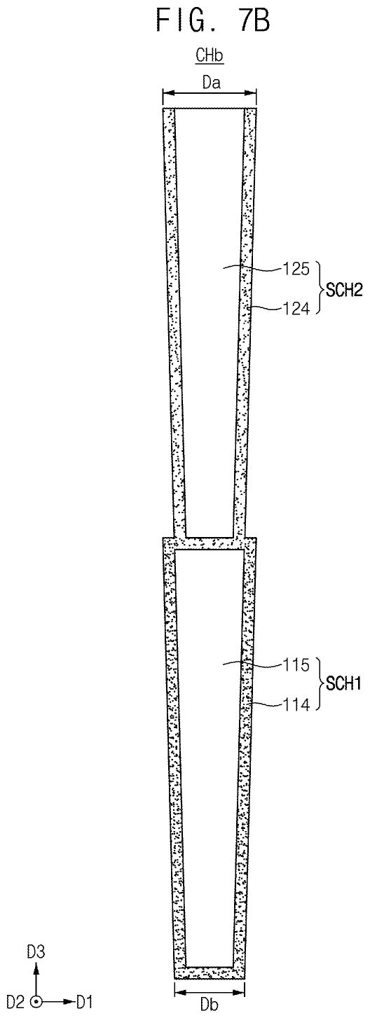

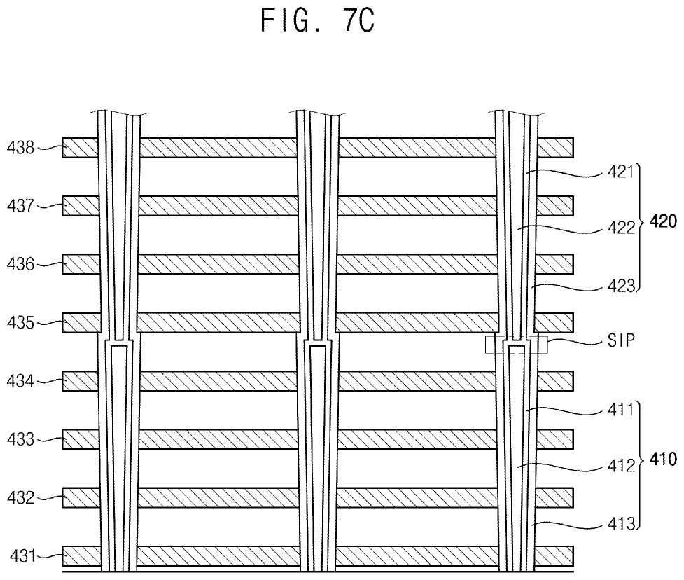

FIGS. 7A, 7B and 7C are cross-sectional views for describing a channel hole included in a nonvolatile memory device according to example embodiments.

Referring to FIG. 7A, a channel hole CHa may correspond to the channel CH in FIG. 2 and the pillar 113 in FIG. 4. A pillar including a channel layer 114 and an internal layer 115 may be formed in a channel hole CHa. For example, the channel hole CHa may be drilled from the top to the bottom, and a diameter Da on a position where the formation of the channel hole CHa starts (e.g., on the top) may be larger than a diameter Db on a position where the formation of the channel hole CHa ends (e.g., on the bottom).

Referring to FIG. 7B, a channel hole CHb may include a first sub-channel hole SCH1 and a second sub-channel hole SCH2. As with the channel hole CHa of FIG. 7A, a pillar including a channel layer 114 and an internal layer 115 may be formed in the first sub-channel hole SCH1, and a pillar including a channel layer 124 and an internal layer 125 may be formed in the second sub-channel hole SCH2. If it is difficult to form one channel hole at once as in the example of FIG. 7A, because of increasing the number of stacked wordlines, one channel hole may be formed using a plurality of sub-channel holes as in the example of FIG. 7B. The example of FIG. 7B may be referred to as a multi-stacked string structure or a multi-stacked structure.

FIG. 7B illustrates a two-stacked structure in which two sub-channel holes SCH1 and SCH2 are sequentially formed or extended along the third direction D3 within one channel hole CHb. For example, the first and second sub-channel holes SCH1 and SCH2 may be sequentially stacked on the first substrate SUB1. For example, the first sub-channel hole SCH1 that is a lower sub-channel hole may be formed first, and then the second sub-channel hole SCH2 that is an upper sub-channel hole may be formed later. However, the present disclosure is not limited thereto, and three or more sub-channel holes may be included in one channel hole.

Referring to FIG. 7C, a channel hole of each cell string may include a first sub-channel hole 410 and a second sub-channel hole 420. A channel hole may be referred to as a pillar. The first sub-channel hole 410 may include a channel layer 411, an internal material 412 and an insulation layer 413. The second sub-channel hole 420 may include a channel layer 421, an internal material 422 and an insulation layer 423. The channel layer 411 of the first sub-channel hole 410 may be connected to the channel layer 421 of the second sub-channel hole 420 through a p-type silicon pad SIP.

The sub-channel holes 410 and 420 may be formed using a stopper line 435 having an appropriate etch rate. For example, the stopper line 435 may be formed of polysilicon and the other wordlines 431, 432, 433, 434, 436, 437 and 438 may be formed of metal such as tungsten to implement the appropriate etch rate. For example, a resistance of the stopper line 435 may be significantly greater than a respective of resistances of the remaining wordlines 431 to 434 and 436 to 438, e.g., by approximately about six times, although there is a difference depending on the doping concentration of polysilicon.

Memory cells connected to the stopper line 435 may not be suitable for storing data, and thus the stopper line 435 and the memory cells connected thereto may be referred to as a dummy wordline and dummy memory cells, respectively. The dummy wordline and the dummy memory cells connected thereto may also be referred to as a buffer unit, a junction unit, etc.

The wordlines 431 to 434 under the stopper line 435, e.g., the wordlines 431 to 434 formed to correspond to the first sub-channel hole 410, may be defined as firstly-stacked wordlines and/or first wordlines. Similarly, the wordlines 436 to 438 on the stopper line 435, e.g., the wordlines 436 to 438 formed to correspond to the second sub-channel hole 420, may be defined as secondly-stacked wordlines and/or second wordlines.

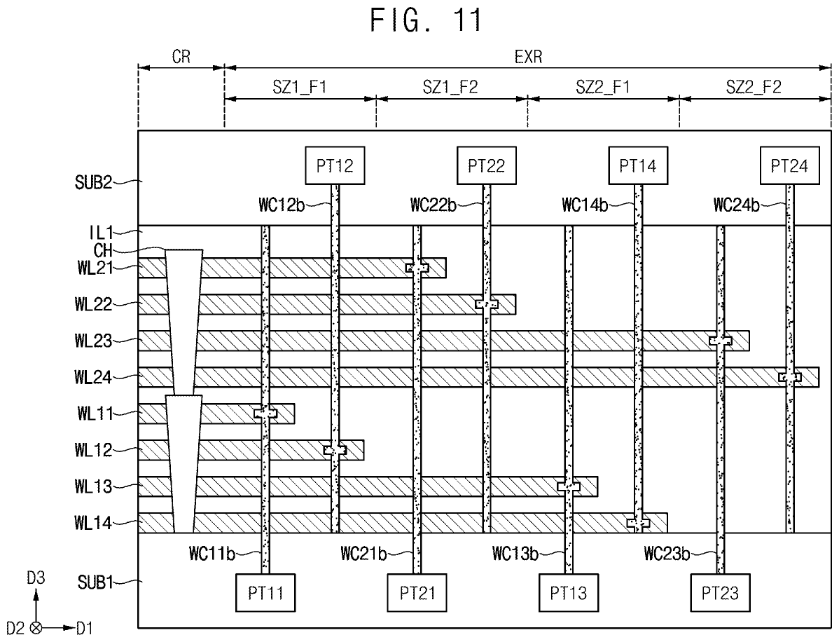

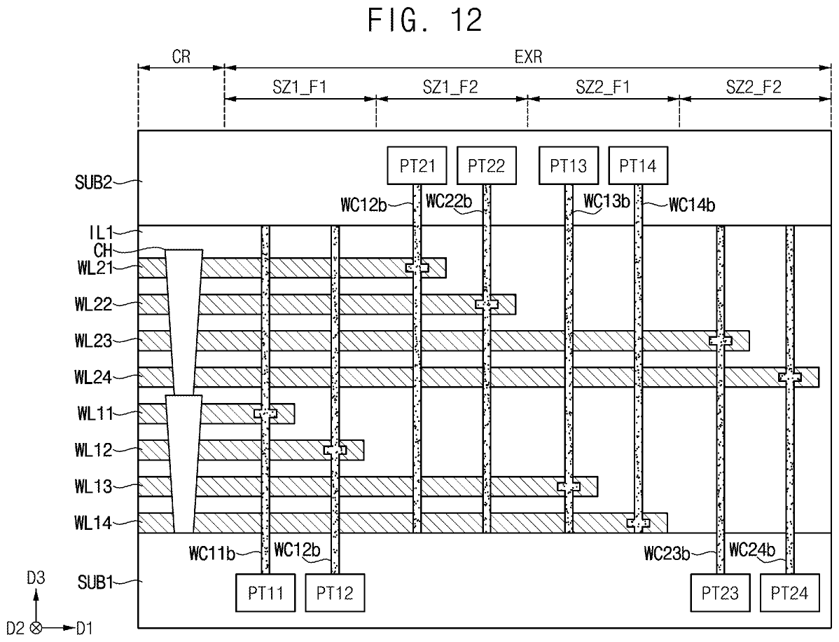

In some example embodiments, when the pass transistors PT are separately arranged according to example embodiments, pass transistors connected to wordlines in the same stack (e.g., wordlines formed to correspond to the same sub-channel hole) may be formed in the same substrate, as will be described with reference to FIG. 9. In some example embodiments, when the pass transistors PT are separately arranged according to example embodiments, wordlines in the same stack may be divided into two or more groups, and pass transistors connected to wordlines of the same group may be formed in the same substrate, as will be described with reference to FIGS. 11 and 12.

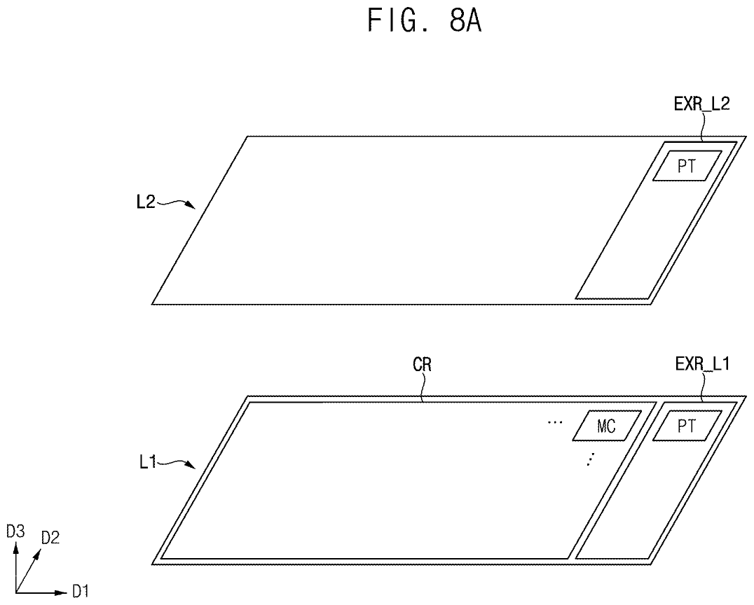

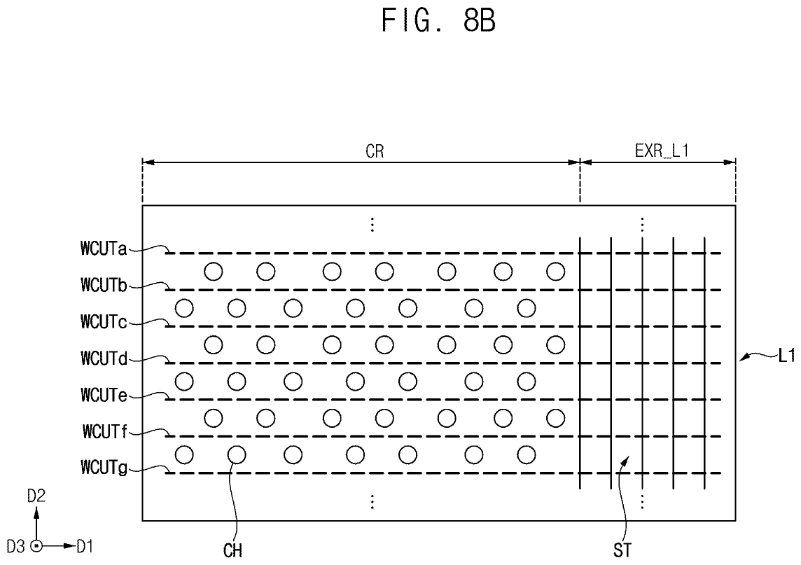

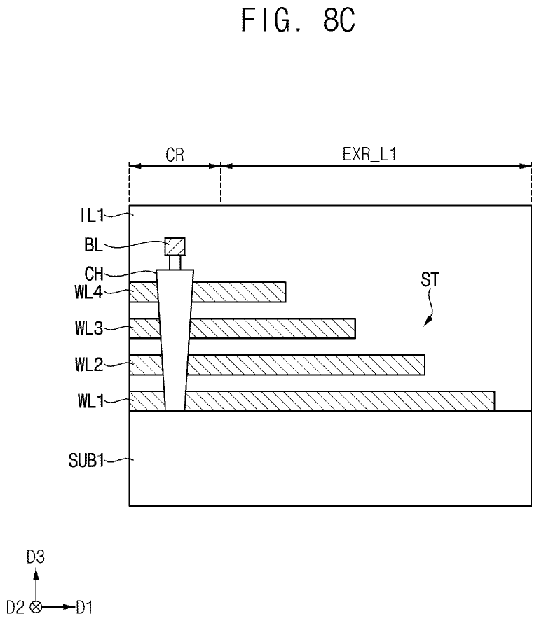

FIGS. 8A, 8B and 8C are diagrams for describing a core region and an extension region that are included in a nonvolatile memory device according to example embodiments.

Referring to FIG. 8A, an example of a layout arrangement of the first and second semiconductor layers L1 and L2 in the nonvolatile memory device 10 of FIG. 1 is illustrated.

The first semiconductor layer L1 may include the memory cell array MCA, and may also include a core region CR and an extension region (or a wordline extension region) EXR_L1. The core region CR may include a plurality of memory cells MC. The extension region EXR_L1 may be formed adjacent to a first side of the core region CR, and may include some of the plurality of pass transistors PT. The extension region EXR_L1 may not include the memory cells MC, and structures for electrically connecting the wordlines WL with other components/circuits may be formed or included in the extension region EXR_L1. For example, as will be described with reference to FIG. 9, the extension region EXR_L1 may include wordline contacts for electrical connections between the wordlines WL and the pass transistors PT.

The second semiconductor layer L2 may include the peripheral circuit PC (not shown), and may also include an extension region EXR_L2 corresponding to the extension region EXR_L1 of the first semiconductor layer L1. For example, when the first and second semiconductor layers L1 and L2 are overlapped and viewed on the same plane, the extension region EXR_L1 and the extension region EXR_L2 may coincide or match. The others of the plurality of pass transistors PT may be formed in the extension region EXR_L2.

Although FIG. 8A illustrates that the first semiconductor layer L1 only includes one extension region EXR_L1 adjacent to the first side of the core region CR, the present disclosure is not limited thereto. For example, the first semiconductor layer L1 may further include a second extension region adjacent to a second side of the core region CR opposite to the first side of the core region CR, and thus the second semiconductor layer L2 may also include two extension regions.

Referring to FIG. 8B, a plan view of the core region CR and the extension region EXR_L1 included in the first semiconductor layer L1 of FIG. 8A is illustrated.

A plurality of channels CH for the memory cells MC may be provided in the core region CR. The channels CH may correspond to the pillars 113 in FIG. 4, and may serve as regions where channels of the NAND string are formed.

A step (or stair) structure ST in which conductive materials for forming the wordlines WL are stacked in a step shape may be provided in the extension region EXR_L1. The conductive materials may correspond to the first conductive materials 211 to 291 in FIG. 4. In the core region CR, the conductive materials may be formed as described with reference to FIG. 4 to form the wordlines WL. However, in the extension region EXR_L1, the conductive materials may be formed as the step structure ST and may electrically connect the wordlines WL with the other components/circuits.

To form the wordlines WL extending in the first direction D1, wordline cut regions WCUTa, WCUTb, WCUTc, WCUTd, WCUTe, WCUTf and WCUTg may be formed as illustrated by thick dotted lines. One wordline extending in the first direction D1 may be formed by two adjacent wordline cut regions.

Referring to FIG. 8C, a cross-sectional view of the core region CR and the extension region EXR_L1 included in the first semiconductor layer L1 of FIG. 8A is illustrated.

The first semiconductor layer L1 may include the first substrate SUB1, and a vertical structure formed on the first substrate SUB1. The first semiconductor layer L1 may also include a contact and the bitline BL that are electrically connected to the vertical structure. The first semiconductor layer L1 may further include a first insulating layer IL1 covering the vertical structure and various conductive lines. The vertical structure may include gate conductive layers disposed on the first substrate SUB1.

In the core region CR, the vertical structure may include the channel CH that penetrates or passes through the gate conductive layers and extend in the third direction D3 on a top surface of the first substrate SUB1. The gate conductive layers may include the wordlines WL1 to WL4. Although not illustrated in detail, the gate conductive layers may further include the ground selection line and the string selection line, and insulating interlayers may be under or over each of the gate conductive layers. For example, the conductive layers (e.g., the wordlines WL1 to WL4) including a conductive material, and the insulating interlayers including an insulation material, may be alternately stacked in the third direction D3.

In the extension region EXR_L1, the vertical structure may include the step structure ST. The step structure ST may be implemented to have a step shape in a cross-sectional view with respect to (or associated with or related to) the wordlines WL1 to WL4

FIG. 9 is a cross-sectional view of an example of a nonvolatile memory device of FIG. 2.

Referring to FIG. 9, a channel CH may have the two-stacked structure described with reference to FIG. 7B. A plurality of wordlines WL11, WL12, WL13, WL14, WL21, WL22, WL23 and WL24 may include first wordlines WL11 to WL14 and second wordlines WL21 to WL24. A plurality of pass transistors PT11, PT12, PT13, PT14, PT21, PT22, PT23 and PT24 may include first pass transistors PT11 to PT14 and second pass transistors PT21 to PT24. For convenience of illustration, ground/string selection lines and ground/string pass transistors are omitted in FIG. 9. Hereinafter, the descriptions repeated with or overlapping with descriptions of FIGS. 2 through 8C will be omitted in the interest of brevity, and example embodiments will be described mainly focusing on a configuration in an extension region EXR.

The first wordlines WL11 to WL14 may be stacked on the first substrate SUB1 in the third direction D3, may be formed to correspond to a first sub-channel hole at the bottom of the channel CH, and may be referred to as firstly-stacked wordlines. The second wordlines WL21 to WL24 may be stacked on the first wordlines WL11 to WL14 in the third direction D3, may be formed to correspond to a second sub-channel hole at the top of the channel CH, and may be referred to as secondly-stacked wordlines. For convenience of illustration, the number of wordlines in one stack is illustrated as four in FIG. 9, however, example embodiments are not limited thereto. In addition, a dummy wordline and/or a buffer unit corresponding to the stopper line 435 in FIG. 7C may be formed or arranged between the first wordlines WL11 to WL14 and the second wordlines WL21 to WL24, but is not shown in FIG. 9.

The first pass transistors PT11 to PT14 may be connected to the first wordlines WL11 to WL14. The second pass transistors PT21 to PT24 may be connected to the second wordlines WL21 to WL24. The first and second pass transistors PT11 to PT14 and PT21 to PT24 may be provided in an extension region EXR. The extension region EXR may correspond to both the extension region EXR_L1 of the first semiconductor layer L1 and the extension region EXR_L2 of the second semiconductor layer L2.

FIG. 9 illustrates an example where the pass transistors connected to the wordlines in the same stack are formed in the same substrate. For example, the first pass transistors PT11 to PT14 may be formed in the first substrate SUB1 of the first semiconductor layer L1, and the second pass transistors PT21 to PT24 may be formed in the second substrate SUB2 of the second semiconductor layer L2.

The extension region EXR may include a plurality of wordline contacts WC11a, WC12a, WC13a, WC14a, WC21a, WC22a, WC23a and WC24a for electrical connections between the plurality of wordlines WL11 to WL14 and WL21 to WL24 and the plurality of pass transistors PT11 to PT14 and PT21 to PT24.

The plurality of wordline contacts WC11a to WC14a and WC21a to WC24a may include first wordline contacts WC11a to WC14a and second wordline contacts WC21a to WC24a. The first wordline contacts WC11a to WC14a may electrically connect the first wordlines WL11 to WL14 with the first pass transistors PT11 to PT14, and the second wordline contacts WC21a to WC24a may electrically connect the second wordlines WL21 to WL24 with the second pass transistors PT21 to PT24.

In some example embodiments, the first wordline contacts WC11a to WC14a and the second wordline contacts WC21a to WC24a may be aligned with each other along the third direction D3. For example, the first wordline contact WCIla and the second wordline contact WC21a may be aligned along the third direction D3. For example, when viewed in a plan view, the first and second wordline contacts WCIla and WC21a that are aligned with each other may be completely overlapped and may be provided at the same location in the first direction D1 and the second direction D2. Although FIG. 9 illustrates that all of the first wordline contacts WC11a to WC14a are aligned with all of the second wordline contacts WC21a to WC24a, respectively, the present disclosure is not limited thereto. For example, some of the first wordline contacts WC11a to WC14a may be aligned with some of the second wordline contacts WC21a to WC24a, and the others of the first wordline contacts WC11a to WC14a may not be aligned with the others of the second wordline contacts WC21a to WC24a.

In some example embodiments, to implement the alignment of the first and second wordline contacts WC11a to WC14a and WC21a to WC24a, each of the first and second wordline contacts WC11a to WC14a and WC21a to WC24a may extend in the third direction D3 such that each wordline contact corresponds to a portion of the first insulating layer IL1. For example, the first wordline contacts WC11a to WC14a may extend in the third direction D3 to correspond only to the first sub-channel hole and the first wordlines WL11 to WL14. For example, the second wordline contacts WC21a to WC24a may extend in the third direction D3 to correspond only to the second sub-channel hole and the second wordlines WL21 to WL24. For example, a height of each of the first and second wordline contacts WC11a and WC21a may be approximately a half of a height of the first insulating layer IL1.

In some example embodiments, the extension region EXR may include a plurality of step zones SZ1 and SZ2 and at least one flat zone FZ. The plurality of step zones SZ1 and SZ2 may have a step shape in a cross-sectional view with respect to at least some of the plurality of wordlines WL11 to WL14 and WL21 to WL24. For example, the step zone SZ1 may have a step shape in a cross-sectional view with respect to the wordlines WL11, WL12, WL21 and WL22, and the step zone SZ2 may have a step shape in a cross-sectional view with respect to the wordlines WL13, WL14, WL23 and WL24. The flat zone FZ may be between two adjacent step zones SZ1 and SZ2, and may have a flat shape in a cross-sectional view with respect to all of the plurality of wordlines WL11 to WL14 and WL21 to WL24.

In some example embodiments, the plurality of wordline contacts WC11a to WC14a and WC21a to WC24a may be formed in the plurality of step zones SZ1 and SZ2 and may not be formed in the flat zone FZ. For example, the wordline contacts WC11a, WC12a, WC21a and WC22a may be formed in the step zone SZ1, and the wordline contacts WC13a, WC14a, WC23a and WC24a may be formed in the step zone SZ2. In other words, the plurality of wordline contacts WC11a to WC14a and WC21a to WC24a may be formed by avoiding the flat zone FZ. Although FIG. 9 illustrates that the pass transistors PT11 to PT14 and PT21 to PT24 are also formed in the step zones SZ1 and SZ2 similar to the wordline contacts WC11a to WC14a and WC21a to WC24a, example embodiments are not limited thereto. For example, some of the pass transistors PT11 to PT14 and PT21 to PT24 may be formed in the flat zone FZ.

In some example embodiments, as the first wordline contacts WC11a to WC14a and the second wordline contacts WC21a to WC24a may be aligned with each other, the step zones and the flat zone for the first wordlines (or firstly-stacked wordlines) WL11 to WL14 and the step zones and the flat zone for the second wordlines (or secondly-stacked wordlines) WL21 to WL24 may be aligned with each other. In other words, the step zone SZ1 may be a step zone for the wordlines WL11 and WL12 and may also be a step zone for the wordlines WL21 and WL22, the step zone SZ2 may be a step zone for the wordlines WL13 and WL14 and may also be a step zone for the wordlines WL23 and WL24, and the flat zone FZ may be a flat zone for all of the wordlines WL11 to WL14 and WL21 to WL24.

As described with reference to FIG. 9, the pass transistors PT11 to PT14 connected to the firstly-stacked wordlines and the pass transistors PT21 to PT24 connected to the secondly-stacked wordlines may be separately arranged in the first substrate SUB1 and the and the second substrate SUB2, respectively. In addition, the pass transistors connected to the wordlines in the same stack may be formed in the same substrate. Further, the wordline contacts WC11a to WC14a connected to the firstly-stacked wordlines and the wordline contacts WC21a to WC24a connected to the secondly-stacked wordlines may be aligned with each other, the step zones for the firstly-stacked wordlines and the step zones for the secondly-stacked wordlines may be aligned with each other, and the flat zone for the firstly-stacked wordlines and the flat zone for the secondly-stacked wordlines may be aligned with each other. Accordingly, the extension region EXR may have a relatively reduced area.

Although not illustrated in FIG. 9, an insulating mold structure including an insulation material filled in the third direction D3 may be formed in the first substrate SUB1, and electrical connections between components may be provided by forming through-hole vias that penetrate the insulating mold structure. In addition, although not illustrated in FIG. 9, to electrically connect the wordlines WL11 to WL14 and WL21 to WL24 with the pass transistors PT11 to PT14 and PT21 to PT24, wafer interconnections or wires within the first and second semiconductor layers L1 and L2 may be additionally formed, and/or bonding pads connecting the first and second semiconductor layers L1 and L2 with each other may be additionally formed.

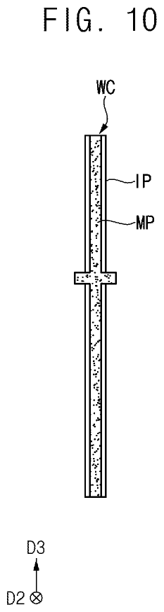

FIG. 10 is a cross-sectional view of an example of a wordline contact included in a nonvolatile memory device of FIG. 9.

Referring to FIG. 10, a wordline contact WC may include an insulating layer pattern IP and a conductive pattern MP, and may further include a protruding portion that protrudes from a target wordline. The wordline contact WC may be electrically connected to the target wordline through the protruding portion of the conductive pattern MP, and may be electrically insulated from other wordlines through the insulating layer pattern IP. However, the present disclosure is not limited thereto, and a configuration of the wordline contact WC may be variously determined according to example embodiments.

FIGS. 11 and 12 are cross-sectional views of examples of a nonvolatile memory device of FIG. 2. The descriptions repeated with FIG. 9 will be omitted.

Referring to FIG. 11, an example where the wordlines in the same stack are divided into two groups and the pass transistors connected to the wordlines of the same group are formed in the same substrate is illustrated.

In an example of FIG. 11, among the wordlines in the same stack, one of odd-numbered wordlines and even-numbered wordlines may be set as a first wordline group (or a first group of wordlines), and the other of the odd-numbered wordlines and the even-numbered wordlines may be set as a second wordline group (or a second group of wordlines).

For example, the first wordlines WL11 to WL14 may be divided into a first wordline group WL11 and WL13 and a second wordline group WL12 and WL14. For example, when the wordline WL11 is the first wordline among the wordlines WL11 to WL14, the first wordline group WL11 and WL13 may include odd-numbered wordlines WL11 and WL13 among the wordlines WL11 to WL14, and the second wordline group WL12 and WL14 may include even-numbered wordlines WL12 and WL14 among the wordlines WL11 to WL14. The plurality of pass transistors PT11 to PT14 may include a first pass transistor group PT11 and PT13 and a second pass transistor group PT12 and PT14. The first pass transistor group PT11 and PT13 may include the pass transistors PT11 and PT13 connected to the first wordline group WL11 and WL13, and the second pass transistor group PT12 and PT14 may include the pass transistors PT12 and PT14 connected to the second wordline group WL12 and WL14. The first pass transistor group PT11 and PT13 may be formed or arranged in the first substrate SUB1 of the first semiconductor layer L1, and the second pass transistor group PT12 and PT14 may be formed or arranged in the second substrate SUB2 of the second semiconductor layer L2.

Similarly, the second wordlines WL21 to WL24 may be divided into a third wordline group WL21 and WL23 and a fourth wordline group WL22 and WL24. The second pass transistors PT21 to PT24 may include a third pass transistor group PT21 and PT23 connected to the third wordline group WL21 and WL23, and a fourth pass transistor group PT22 and PT24 connected to the fourth wordline group WL22 and WL24. The third pass transistor group PT21 and PT23 may be formed in the first substrate SUB1 of the first semiconductor layer L1, and the fourth pass transistor group PT22 and PT24 may be formed in the second substrate SUB2 of the second semiconductor layer L2.

Although not illustrated in detail, in some example embodiments, the pass transistors PT11, PT13, PT21 and PT23 may be formed in the second substrate SUB2, and the pass transistors PT12, PT14, PT22 and PT24 may be formed in the first substrate SUB1.

In some example embodiments, in the first substrate SUB1, the first pass transistor group PT11 and PT13 and the third pass transistor group PT21 and PT23 may be alternately arranged one by one along the first direction D1. Similarly, in the second substrate SUB2, the second pass transistor group PT12 and PT14 and the fourth pass transistor group PT22 and PT24 may be alternately arranged one by one along the first direction D1.

The extension region EXR may include a plurality of wordline contacts WC11b, WC12b, WC13b, WC14b, WC21b, WC22b, WC23b and WC24b for electrical connections between the plurality of wordlines WL11 to WL14 and WL21 to WL24 and the plurality of pass transistors PT11 to PT14 and PT21 to PT24. The plurality of wordline contacts WC11b to WC14b and WC21b to WC24b may include first wordline contacts WC11b to WC14b and second wordline contacts WC21b to WC24b. The first wordline contacts WC11b to WC14b may include a first wordline contact group WC11b and WC13b and a second wordline contact group WC12b and WC14b. The first wordline contact group WC11b and WC13b may electrically connect the first wordline group WL11 and WL13 with the first pass transistor group PT11 and PT13. The second wordline contact group WC12b and WC14b may electrically connect the second wordline group WL12 and WL14 with the second pass transistor group PT12 and PT14. The second wordline contacts WC21b to WC24b may include a third wordline contact group WC21b and WC23b, and a fourth wordline contact group WC22b and WC24b. The third wordline contact group WC21b and WC23b may electrically connect the third wordline group WL21 and WL23 with the third pass transistor group PT21 and PT23. The fourth wordline contact group WC22b and WC24b may electrically connect the fourth wordline group WL22 and WL24 with the fourth pass transistor group PT22 and PT24.

In some example embodiments, the first wordline contact group WC11b and WC13b, the second wordline contact group WC12b and WC14b, the third wordline contact group WC21b and WC23b, and the fourth wordline contact group WC22b and WC24b may be alternately arranged one by one along the first direction D1.

In some example embodiments, each of the plurality of wordline contacts WC11b to WC14b and WC21b to WC24b may extend in the third direction D3 such that each wordline contact corresponds to the entire of first insulating layer IL1. For example, a height of each of the plurality of wordline contacts WC11b to WC14b and WC21b to WC24b may be substantially equal to the height of the first insulating layer IL1. Therefore, unlike the example of FIG. 9, the plurality of wordline contacts WC11b to WC14b and WC21b to WC24b may not be aligned along the third direction D3.

In some example embodiments, the extension region EXR may include first step zones SZ1_F1 and SZ2_F1 and second step zones SZ1_F2 and SZ2_F2. The first step zones SZ1_F1 and SZ2_F1 may have a step shape in a cross-sectional view with respect to at least some of the first wordlines WL11 to WL14, and the second step zones SZ1_F2 and SZ2_F2 may have a step shape in a cross-sectional view with respect to at least some of the second wordlines WL21 to WL24. For example, the first step zone SZ1_F1 may have a step shape in a cross-sectional view with respect to the first wordlines WL11 and WL12, and the second step zone SZ1_F2 may have a step shape in a cross-sectional view with respect to the second wordlines WL21 and WL22.

In some example embodiments, the first wordline contact group WC11b and WC13b and the second wordline contact group WC12b and WC14b may be formed in the first step zones SZ1_F1 and SZ2_F1. The third wordline contact group WC21b and WC23b and the fourth wordline contact group WC22b and WC24b may be formed in the second step zones SZ1_F2 and SZ2_F2.

In some example embodiments, the first step zones SZ1_F1 and SZ2_F1 and the second step zones SZ1_F2 and SZ2_F2 may be alternately arranged one by one along the first direction D1. When the first step zones SZ1_F1 and SZ2_F1 and the second step zones SZ1_F2 and SZ2_F2 are alternately arranged alternately, at least one first flat zone between the first step zones SZ1_F1 and SZ2_F1 may be omitted or minimized, and at least one second flat zone between the second step zones SZ1_F2 and SZ2_F2 may be omitted or minimized. FIG. 11 illustrates that the first flat zone and the second flat zone are omitted.

Referring to FIG. 12, an example where the wordlines in the same stack are divided into two groups and the pass transistors connected to the wordlines of the same group are formed in the same substrate is illustrated. The descriptions repeated with FIG. 11 will be omitted.

In an example of FIG. 12, among the wordlines in the same stack, K wordlines sequentially or continuously stacked in the third direction D3 may be set as a first wordline group, and then the other K wordlines sequentially stacked in the third direction D3 may be set as a second wordline group, where K is a positive integer greater than or equal to two. For example, FIG. 12 illustrates a case where K=2.

For example, the first wordlines WL11 to WL14 may be divided into a first wordline group WL11 and WL12 and a second wordline group WL13 and WL14. For example, among the first wordlines WL11 to WL14, the first wordline group WL11 and WL12 may include two wordlines WL11 and WL12 that are sequentially stacked, and the second wordline group WL13 and WL14 may include two wordlines WL13 and WL14 that are sequentially stacked and adjacent to the first wordline group WL11 and WL12. Although not illustrated in detail, when the first wordlines further include wordlines WL1A, WL1B, WL1C and WL1D sequentially formed under the wordline WL14, the wordlines WL1A and WL1B may be included in the first wordline group, and the wordlines WL1C and WL1D may be included in the second wordline group. Among the first pass transistors PT11 to PT14 connected to the first wordlines WL11 to WL14, a first pass transistor group PT11 and PT12 connected to the first wordline group WL11 and WL12 may be formed in the first substrate SUB1 of the first semiconductor layer L1, and a second pass transistor group PT13 and PT14 connected to the second wordline group WL13 and WL14 may be formed in the second substrate SUB2 of the second semiconductor layer L2.

Similarly, the second wordlines WL21 to WL24 may be divided into a third wordline group WL21 and WL22 and a fourth wordline group WL23 and WL24. Among the second pass transistors PT21 to PT24 connected to the second wordlines WL21 to WL24, a third pass transistor group PT21 and PT22 connected to the third wordline group WL21 and WL22 may be formed in the second substrate SUB2 of the second semiconductor layer L2, and a fourth pass transistor group PT23 and PT24 connected to the fourth wordline group WL23 and WL24 may be formed in the first substrate SUB1 of the first semiconductor layer L1.

Although not illustrated in detail, in some example embodiments, the pass transistors PT21 and PT22 may be formed in the first substrate SUB1, and the pass transistors PT23 and PT24 may be formed in the second substrate SUB2. In some example embodiments, the pass transistors PT11, PT12, PT23 and PT24 may be formed in the second substrate SUB2, and the pass transistors PT13, PT14, PT21 and PT22 may be formed in the first substrate SUB1.

In some example embodiments, in the first substrate SUB1, the first pass transistor group PT11 and PT12 and the fourth pass transistor group PT23 and PT24 may be alternately arranged two by two (e.g., K by K) along the first direction D1. In the second substrate SUB2, the third pass transistor group PT21 and PT22 and the second pass transistor group PT13 and PT14 may be alternately arranged two by two along the first direction D1.

In some example embodiments, the first wordline contact group WC11b and WC12b, the third wordline contact group WC21b and WC22b, the second wordline contact group WC13b and WC14b, and the fourth wordline contact group WC23b and WC24b may be alternately arranged two by two along the first direction D1.

As described with reference to FIGS. 11 and 12, the pass transistors PT11 to PT14 connected to the firstly-stacked wordlines and the pass transistors PT21 to PT24 connected to the secondly-stacked wordlines may be separately arranged in the first substrate SUB1 and the and the second substrate SUB2, respectively. In addition, the wordlines in the same stack may be divided into two groups, and the pass transistors connected to the wordlines of the same group may be formed in the same substrate. Further, the flat zone between the step zones may be omitted or minimized. Accordingly, the extension region EXR may have a relatively reduced area.

Although FIGS. 11 and 12 illustrate that the wordlines in the same stack are divided into two groups, example embodiments are not limited thereto. For example, the wordlines in the same stack may be grouped in at least one of various manners.

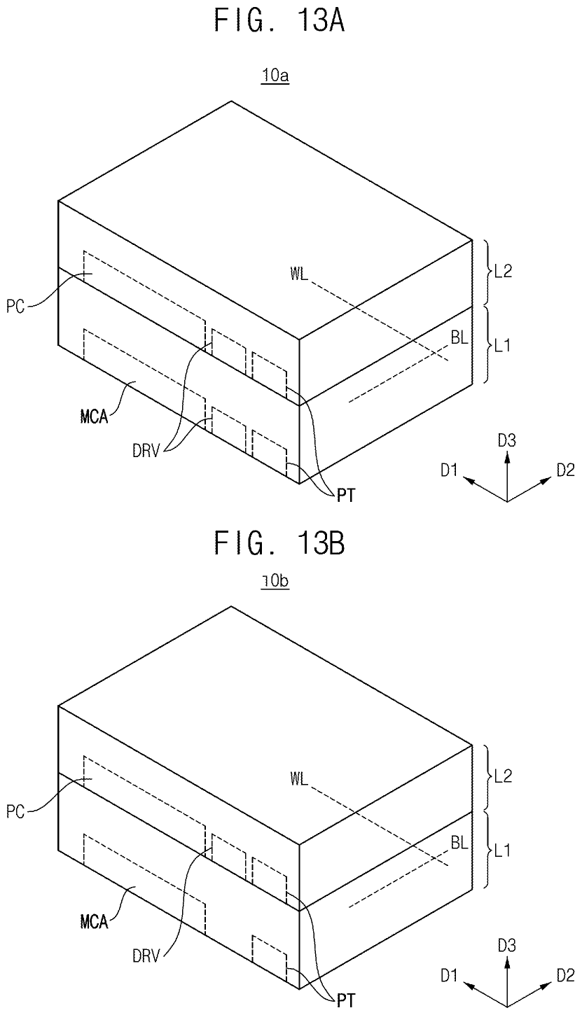

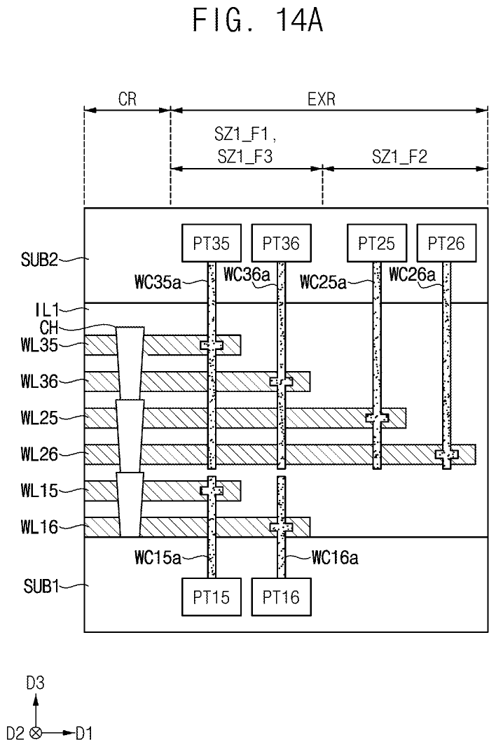

FIGS. 13A and 13B are perspective views of a nonvolatile memory device according to example embodiments. The descriptions repeated with FIG. 1 will be omitted.

Referring to FIG. 13A, a nonvolatile memory device 10a may include a first semiconductor layer L1, a second semiconductor layer L2 and a plurality of pass transistors PT, and may further include a plurality of drivers DRV.

The plurality of drivers DRV may control switching operations of the plurality of pass transistors PT. For example, the plurality of drivers DRV may correspond to the plurality of drivers 524 in FIG. 3, and may correspond to at least a part of the driver circuit 620 in FIG. 6.

As described with reference to FIG. 2, when the plurality of pass transistors PT include the first and second pass transistors PTa and PTb, the plurality of drivers DRV may include a first driver that is configured to control a switching operation of the first pass transistor PTa, and a second driver that is configured to control a switching operation of the second pass transistor PTb. For example, the first driver may be formed in the first substrate SUB1 of the first semiconductor layer L1 and may be adjacent to the first pass transistor PTa, and the second driver may be formed in the second substrate SUB2 of the second semiconductor layer L2 and may be adjacent to the second pass transistor PTb.

Referring to FIG. 13B, a nonvolatile memory device 10b includes a first semiconductor layer L1, a second semiconductor layer L2 and a plurality of pass transistors PT, and may further include a plurality of drivers DRV.

The nonvolatile memory device 10b may be substantially the same as the non-volatile memory device 10a of FIG. 13A, except that the plurality of drivers DRV, e.g. both the first and second drivers, are formed in the second substrate SUB2 of the second semiconductor layer L2.

Although not illustrated in detail, in some example embodiments, the plurality of drivers DRV, e.g. both the first and second drivers, may be formed in the first substrate SUB1 of the first semiconductor layer L1.

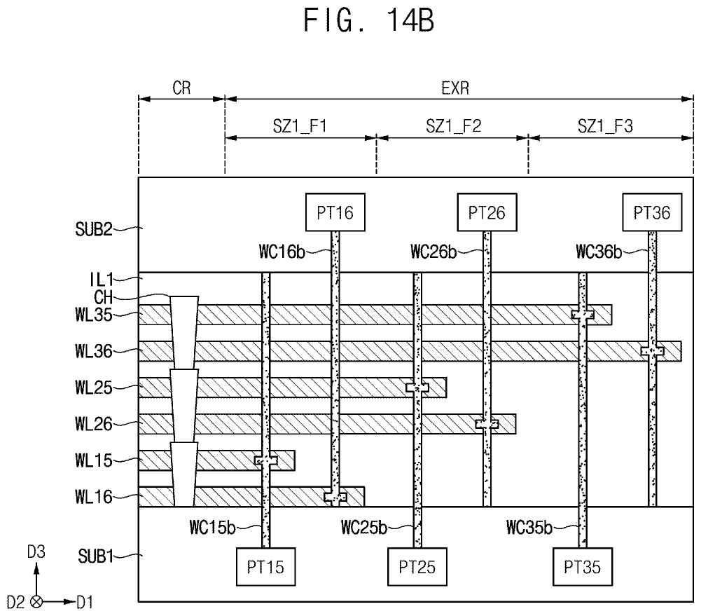

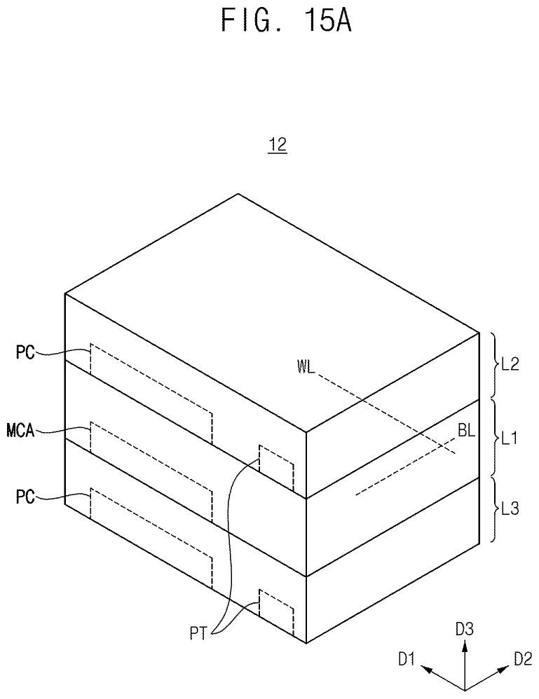

FIGS. 14A and 14B are cross-sectional views of examples of a nonvolatile memory device of FIG. 2. The descriptions repeated with FIGS. 9, 11 and 12 will be omitted.

Referring to FIG. 14A, a channel CH may have a three-stacked structure. A plurality of wordlines WL15, WL16, WL25, WL26, WL35 and WL36 may include are first wordlines WL15 and WL16, second wordlines WL25 and WL26, and third wordlines WL35 and WL36. A plurality of pass transistors PT15, PT16, PT25, PT26, PT35 and PT36 may include first pass transistors PT15 and PT16, second pass transistors PT25 and PT26, and third pass transistors PT35 and PT36.

The first wordlines WL15 and WL16 may be stacked on the first substrate SUB1 in the third direction D3, and may be formed to correspond to a first sub-channel hole at the bottom of the channel CH. The second wordlines WL25 and WL26 may be stacked on the first wordlines WL15 and WL16 in the third direction D3, and may be formed to correspond to a second sub-channel hole in the middle of the channel CH. The third wordlines WL35 and WL36 may be stacked on the second wordlines WL25 and WL26 in the third direction D3, and may be formed to correspond to a third sub-channel hole at the top of the channel CH. For convenience of illustration, the number of wordlines in one stack is illustrated as two in FIG. 14A, with the understanding that the present disclosure is not limited thereto.

The first pass transistors PT15 and PT16 may be connected to the first wordlines WL15 and WL16, the second pass transistors PT25 and PT26 may be connected to the second wordlines WL25 and WL26, and the third pass transistors PT35 and PT36 may be connected to the third wordlines WL35 and WL36. First wordline contacts WC15a and WC16a may electrically connect the first wordlines WL15 and WL16 with the first pass transistors PT15 and PT16, second wordline contacts WC25a and WC26a may electrically connect the second wordlines WL25 and WL26 with the second pass transistors PT25 and PT26, and third wordline contacts WC35a and WC36a may electrically connect the third wordlines WL35 and WL36 with the third pass transistors PT35 and PT36.

As with the example of FIG. 9, FIG. 14A illustrates an example where the pass transistors connected to the wordlines in the same stack are formed in the same substrate, and at least some of the wordline contacts WC15a, WC16a, WC25a, WC26a, WC35a and WC36a are aligned along the third direction D3. For example, the first pass transistors PT15 and PT16 may be formed in the first substrate SUB1 of the first semiconductor layer L1, the third pass transistors PT35 and PT36 may be formed in the second substrate SUB2 of the second semiconductor layer L2, and the first wordline contacts WC15a and WC16a and the third wordline contacts WC35a and WC36a may be aligned with each other along the third direction D3. For example, the second pass transistors PT25 and PT26 may be formed in the second substrate SUB2 of the second semiconductor layer L2. For example, the extension region EXR may include step zones SZ1_F1, SZ1_F2 and SZ1_F3, and the wordline contacts WC15a, WC16a, WC25a, WC26a, WC35a and WC36a may be formed in the step zones SZ1_F1, SZ1_F2 and SZ1_F3.

Although not illustrated in detail, in some example embodiments, the second pass transistors PT25 and PT26 may be formed in the first substrate SUB1 of the first semiconductor layer L1.

Although not illustrated in detail, in some example embodiments, when a channel has a four-stacked structure, pass transistors connected to wordlines formed to correspond to two lower sub-channel holes may be formed in the first substrate SUB1, and pass transistors connected to wordlines formed to correspond to two upper sub-channel holes may be formed in the second substrate SUB2.

Referring to FIG. 14B, an example where the wordlines in the same stack are divided into two groups and the pass transistors connected to the wordlines of the same group are formed in the same substrate is illustrated. The descriptions repeated with FIGS. 11 and 14A will be omitted here in the interest of brevity.

As with the examples of FIGS. 11 and 12, FIG. 14B illustrates an example where one of the odd-numbered wordlines and the even-numbered wordlines among the wordlines in the same stack is set as a first wordline group, the other of the odd-numbered wordlines and the even-numbered wordlines is set as a second wordline group, and wordline contacts WC15b, WC16b, WC25b, WC26b, WC35b and WC36b are alternately arranged along the first direction D1.

For example, the first wordlines WL15 and WL16 may include a first wordline group WL15 and a second wordline group WL16, the first pass transistors PT15 and PT16 may include a first pass transistor group PT15 and a second pass transistor group PT16, and the first wordline contacts WC15b and WC16b may include a first wordline contact group WC15b and a second wordline contact group WC16b. The first pass transistor group PT15 connected to the first wordline group WL15 through the first wordline contact group WC15b may be formed in the first substrate SUB1 of the first semiconductor layer L1. The second pass transistor group PT16 connected to the second wordline group WL16 through the second wordline contact group WC16b may be formed in the second substrate SUB2 of the second semiconductor layer L2.

Similarly, each of the second wordlines WL25 and WL26, the second pass transistors PT25 and PT26, and the second wordline contacts WC25b and WC26b may be divided into two groups, and the second pass transistors PT25 and PT26 may be separately arranged in the first and second substrates SUB1 and SUB2, respectively. Each of the third wordlines WL35 and WL36, the third pass transistors PT35 and PT36, and the third wordline contacts WC35b and WC36b may be divided into two groups, and the third pass transistors PT35 and PT36 may be separately arranged in the first and second substrates SUB1 and SUB2, respectively. For example, the extension region EXR may include step zones SZ1_F1, SZ1_F2 and SZ1_F3, and the wordline contacts WC15b, WC16b, WC25b, WC26b WC35b and WC36b may be formed in the step zones SZ1_F1, SZ1_F2 and SZ1_F3.

FIGS. 15A, 15B, 15C, 15D and 15E are diagrams illustrating a nonvolatile memory device according to some example embodiments.

Referring to FIG. 15A, a nonvolatile memory device 12 includes a first semiconductor layer L1, a second semiconductor layer L2 and a third semiconductor layer L3.

An example of FIG. 15A may be substantially the same as the example of FIG. 1, except that the nonvolatile memory device 12 further includes the third semiconductor layer L3 and an arrangement of the pass transistors PT is partially changed. The descriptions repeated with FIG. 1 will be omitted.

The first semiconductor layer L1, the second semiconductor layer L2 and the third semiconductor layer L3 may be arranged or stacked in the third direction D3. The nonvolatile memory device 12 may have as a multi-wafer stacked (or bonded) structure in which three or more semiconductor layers are stacked and/or bonded.

As with the second semiconductor layer L2, the third semiconductor layer L3 may also include a peripheral circuit PC that controls the memory cell array MCA, and thus the third semiconductor layer L3 may be referred to as a peripheral circuit region. For example, the peripheral circuit PC included in the second semiconductor layer L2 may be defined as a first peripheral circuit, and the peripheral circuit PC included in the third semiconductor layer L3 may be defined as a second peripheral circuit. For example, the first and second peripheral circuits may include a control circuit, a page buffer circuit, and/or the like.

Some (e.g., a first part) of the pass transistors PT may be formed in the second semiconductor layer L2, and the others (e.g., a second part) of the pass transistors PT may be formed in the third semiconductor layer L3. In other words, the pass transistors PT may be separated and/or distributed in the second and third semiconductor layers L2 and L3. Thus, an area in which where the pass transistors PT are placed within one semiconductor layer may be reduced, and the wiring complexity for connecting the pass transistors PT with the wordlines WL may be reduced. Accordingly, the circuit area may be reduced, the manufacturing cost may be reduced, and thus the nonvolatile memory device 12 may be efficiently manufactured.

Referring to FIG. 15B, a first semiconductor layer L1 may include a first substrate SUB1, first and second wordlines WLa and WLb, channels CH, and a first insulating layer IL1. A second semiconductor layer L2 may include a second substrate SUB2, a second pass transistor PTb, and a second insulating layer IL2. A third semiconductor layer L3 may include a third substrate SUB3, a first pass transistor PTa, and a third insulating layer IL3.

An example of FIG. 15B may be substantially the same as the example of FIG. 2, except that the third semiconductor layer L3 is further formed and the first pass transistor PTa is formed in the third substrate SUB3. The descriptions repeated with FIG. 2 will be omitted.

Referring to FIG. 15C, an example where the pass transistors connected to the wordlines in the same stack are formed in the same substrate is illustrated. An example of FIG. 15C may be substantially the same as the example of FIG. 9, except that the first pass transistors PT11 to PT14 are formed in the third substrate SUB3 of the third semiconductor layer L3. The descriptions repeated with FIG. 9 will be omitted.

Referring to FIGS. 15D and 15E, examples where the wordlines in the same stack are divided into two groups and the pass transistors connected to the wordlines of the same group are formed in the same substrate are illustrated. An example of FIG. 15D may be substantially the same as the example of FIG. 11, except that the first pass transistor group PT11 and PT13 and the third pass transistor group PT21 and PT23 are formed in the third substrate SUB3 of the third semiconductor layer L3. An example of FIG. 15E may be substantially the same as the example of FIG. 12, except that the first pass transistor group PT11 and PT12 and the fourth pass transistor group PT23 and PT24 are formed in the third substrate SUB3 of the third semiconductor layer L3. The descriptions repeated with FIGS. 11 and 12 will be omitted.

FIGS. 16A, 16B, 16C and 16D are diagrams illustrating a nonvolatile memory device according to some example embodiments.

Referring to FIG. 16A, a nonvolatile memory device 14 may include a first semiconductor layer L1, a second semiconductor layer L2 and a third semiconductor layer L3.

An example of FIG. 16A may be substantially the same as the example of FIG. 1, except that the nonvolatile memory device 14 further includes the third semiconductor layer L3 and an arrangement of the pass transistors PT may be partially changed. The third semiconductor layer L3 in FIG. 16A may be substantially the same as the third semiconductor layer L3 in FIG. 15A. The descriptions repeated with FIGS. 1 and 15A will be omitted.

Some (e.g., a first part) of the pass transistors PT may be formed in the first semiconductor layer L1, others (e.g., a second part) of the pass transistors PT may be formed in the second semiconductor layer L2, and the remainder (e.g., a third part) of the pass transistors PT may be formed in the third semiconductor layer L3. In other words, the pass transistors PT may be separated and/or distributed in the first, second and third semiconductor layers L1, L2 and L3. Thus, an area in which where the pass transistors PT are placed within one semiconductor layer may be reduced, and the wiring complexity for connecting the pass transistors PT with the wordlines WL may be reduced. Accordingly, the circuit area may be reduced, the manufacturing cost may be reduced, and thus the nonvolatile memory device 12 may be manufactured more efficiently.

Referring to FIG. 16B, a first semiconductor layer L1 may include a first substrate SUB1, first, second and third wordlines WLa, WLb and WLc, channels CH, a first pass transistor PTa, and a first insulating layer IL1. A second semiconductor layer L2 may include a second substrate SUB2, a second pass transistor PTb, and a second insulating layer IL2. A third semiconductor layer L3 may include a third substrate SUB3, a third pass transistor PTc, and a third insulating layer IL3.

An example of FIG. 16B may be substantially the same as the example of FIG. 2, except that the third semiconductor layer L3 and the third pass transistor PTc are further formed. The third semiconductor layer L3 in FIG. 16B may be substantially the same as the third semiconductor layer L3 in FIG. 15B. The descriptions repeated with FIGS. 2 and 15B will be omitted here in the interest of brevity.

The wordlines WLa, WLb and WLc may be stacked on the first substrate SUB1 in the third direction D3. The channels CH may penetrate the wordlines WLa, WLb and WLc, and may extend in a direction perpendicular to the top surface of the first substrate SUB1. The third pass transistor PTc may be formed in the third substrate SUB3, and may be connected to the third wordline WLc.

In some example embodiments, at least one of widths and lengths of the first pass transistor PTa, the second pass transistor PTb and the third pass transistor PTc may be different from each other.

Referring to FIG. 16C, an example where the pass transistors connected to the wordlines in the same stack are formed in the same substrate is illustrated. An example of FIG. 16C may be substantially the same as the examples of FIGS. 14A and 14B, except that the second pass transistors PT25 and PT26 may be formed in the third substrate SUB3 of the third semiconductor layer L3. The descriptions repeated with FIGS. 14A and 14B will be omitted here in the interest of brevity.

Referring to FIG. 16D, an example where the wordlines in the same stack are divided into three groups and the pass transistors connected to the wordlines of the same group are formed in the same substrate is illustrated. The descriptions repeated with FIGS. 11 and 15D will be omitted here in the interest of brevity.

First wordlines WL17, WL18 and WL19 may include a first wordline group WL17, a second wordline group WL18 and a third wordline group WL19, first pass transistors PT17, PT18 and PT19 may include a first pass transistor group PT17, a second pass transistor group PT18 and a third pass transistor group PT19, and first wordline contacts WC17b, WC18b and WC19b may include a first wordline contact group WC17b, a second wordline contact group WC18b and a third wordline contact group WC19b. The first pass transistor group PT17 connected to the first wordline group WL17 through the first wordline contact group WC17b may be formed in the first substrate SUB1. The second pass transistor group PT18 connected to the second wordline group WL18 through the second wordline contact group WC18b may be formed in the second substrate SUB2. The third pass transistor group PT19 connected to the third wordline group WL19 through the third wordline contact group WC19b may be formed in the third substrate SUB3.

Similarly, each of second wordlines WL27, WL28 and WL29, second pass transistors PT27, PT28 and PT29, and second wordline contacts WC27b, WC28b and WC29b may be divided into three groups, and the second pass transistors PT27, PT28, and PT29 may be separately arranged in the first, second and third substrates SUB1, SUB2 and SUB3, respectively. The wordline contacts WC17b, WC18b, WC19b, WC27b, WC28b and WC29b may be formed in step zones SZ1_F1 and SZ1_F2.

Although example embodiments are described based on a specific number of semiconductor layers, a specific number of sub-channel holes, a specific number of wordlines and a specific number of pass transistors, the present disclosure is not limited thereto. For example, the nonvolatile memory device according to example embodiments may include any number of semiconductor layers, any number of sub-channel holes, any number of wordlines and/or any number of pass transistors.

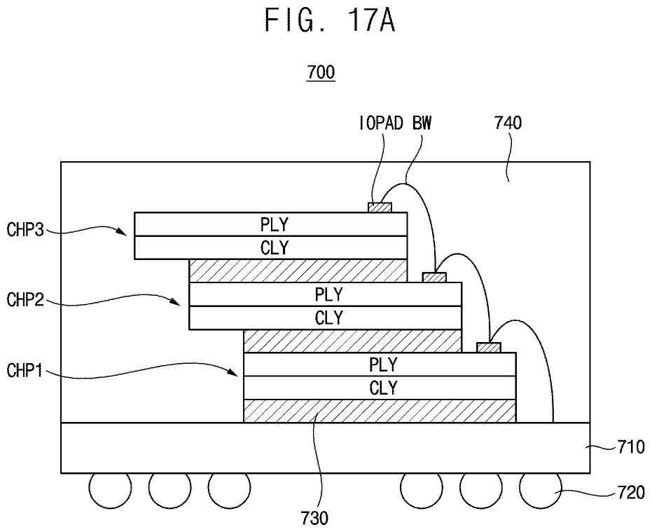

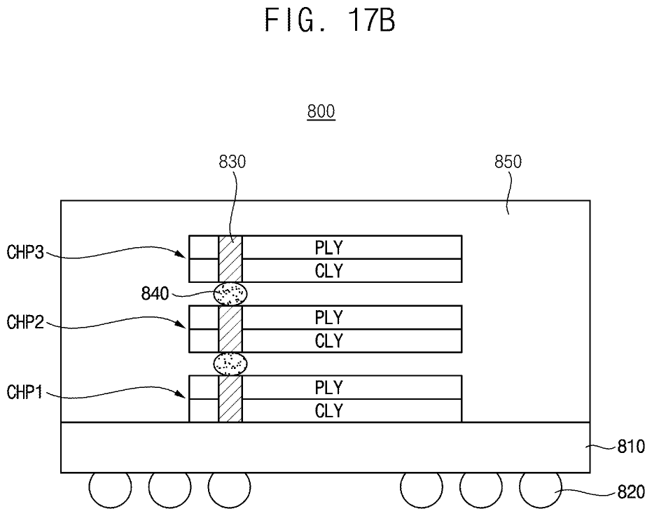

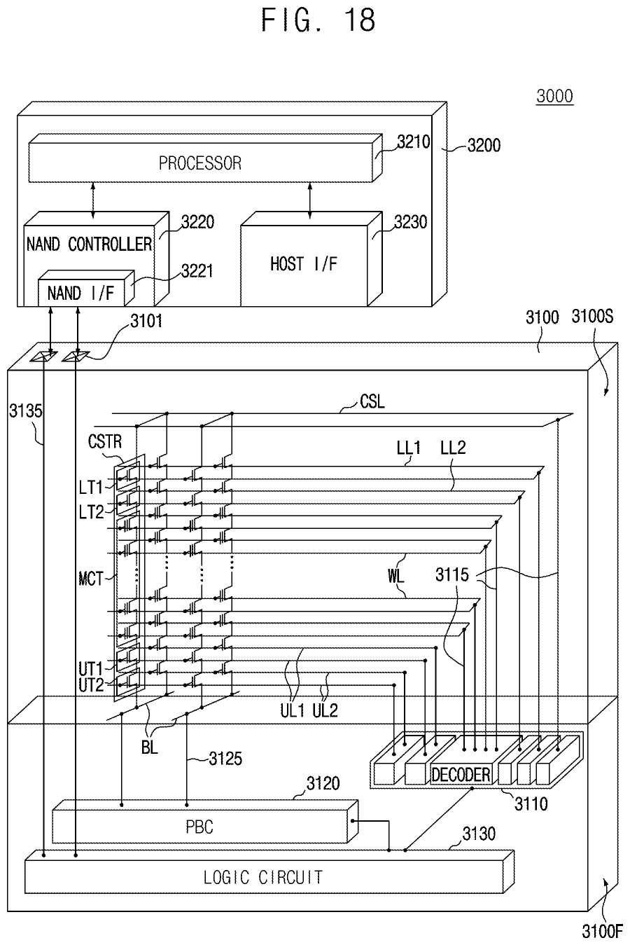

FIGS. 17A and 17B are cross-sectional views of a memory package according to some example embodiments.

Referring to FIG. 17A, a memory package 700 may include a base substrate 710 and a plurality of memory chips CHP1, CHP2 and CHP3 stacked on the base substrate 710.

Each of the memory chips CHP1 to CHP3 may include a memory cell layer CLY and a peripheral circuit layer PLY, and may further include a plurality of I/O pads IOPAD. The memory cell layer CLY and the peripheral circuit layer PLY may correspond to the first semiconductor layer L1 and the second semiconductor layer L2 described with reference to FIG. 1, respectively, and further may include said elements described herein to be included in the first semiconductor layer L1 and the second semiconductor layer L2, respectively, according to any of the example embodiments described herein. Each of the memory chips CHP1 to CHP3 may include the nonvolatile memory device according to example embodiments.

In some example embodiments, the memory chips CHP1 to CHP3 may be stacked on the base substrate 710 such that a surface on which the plurality of I/O pads IOPAD are formed faces upwards. In some example embodiments, with respect to each of the memory chips CHP1 to CHP3, the plurality of I/O pads IOPAD may be arranged near one side of the semiconductor substrate. As such, the memory chips CHP1 to CHP3 may be stacked scalariformly, that is, in a step shape, such that the plurality of I/O pads IOPAD of each memory chip may be exposed. In such stacked state, the memory chips CHP1 to CHP3 may be electrically connected to the base substrate 710 through a plurality of bonding wires BW.

The stacked memory chips CHP1 to CHP3 and the plurality of bonding wires BW may be fixed by a sealing member 740, and adhesive members 730 may intervene between the base substrate 710 and the memory chips CHP1 to CHP3. Conductive bumps 720 may be formed on a bottom surface of the base substrate 710 for electrical connections to an external device.

Referring to FIG. 17B, a memory package 800 may include a base substrate 810 and the plurality of memory chips CHP1 to CHP3 stacked on the base substrate 810. The descriptions repeated with FIG. 17A will be omitted.

Each of the memory chips CHP1 to CHP3 may include the memory cell layer CLY and the peripheral circuit layer PLY, and may further include a plurality of through silicon vias (TSVs) 830.

In some example embodiments, with respect to each of the memory chips CHP1 to CHP3, the plurality of TSVs 830 may be arranged at the same locations in each memory chip. As such, the memory chips CHP1 to CHP3 may be stacked such that the plurality of TSVs 830 of each memory chip may be completely overlapped (e.g., arrangements of the plurality of TSVs 830 may be perfectly matched in the memory chips CHP1 to CHP3). In such stacked state, the memory chips CHP1 to CHP3 may be electrically connected to one another and the base substrate 810 through the plurality of TSVs 830 and conductive material 840.

Conductive bumps 820 and a sealing member 850 may be substantially the same as the conductive bumps 720 and the sealing member 740 in FIG. 17A.

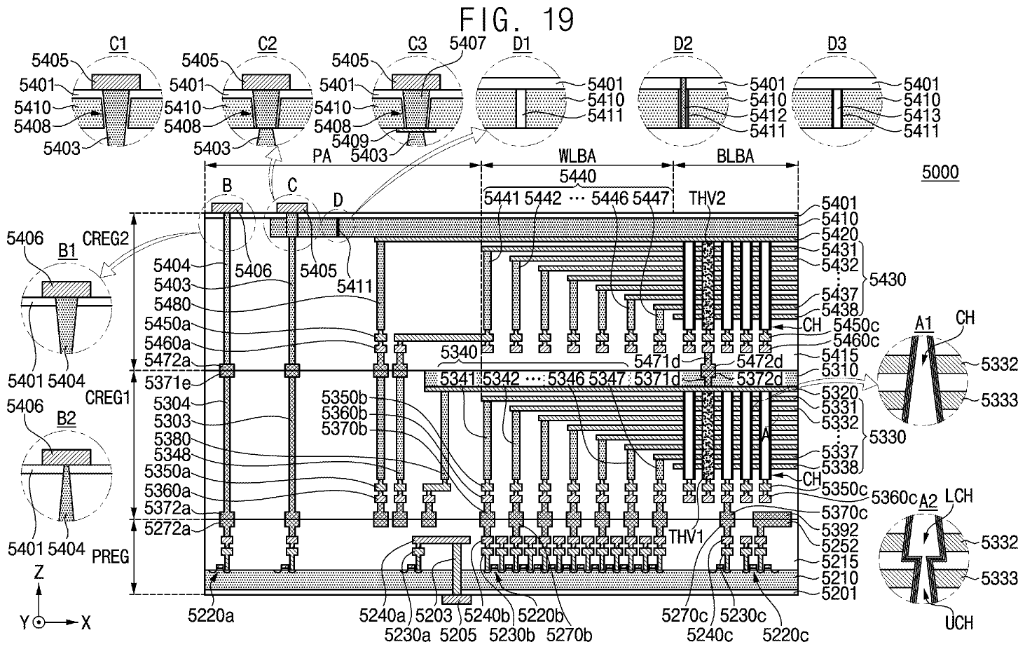

FIG. 18 is a block diagram illustrating an electronic system including a nonvolatile memory device according to some example embodiments.

Referring to FIG. 18, an electronic system 3000 may include a semiconductor device 3100 and a controller 3200 electrically connected to the semiconductor device 3100. The electronic system 3000 may be a storage device including one or a plurality of semiconductor devices 3100 or an electronic device including the storage device. For example, the electronic system 3000 may be a solid state drive (SSD) device, a universal serial bus (USB), a computing system, a medical device, or a communication device that may include one or a plurality of semiconductor devices 3100.

The semiconductor device 3100 may be a nonvolatile memory device, for example, the nonvolatile memory device according to example embodiments described with reference to FIGS. 1 through 16D. The semiconductor device 3100 may include a first structure 3100F and a second structure 3100S on the first structure 3100F. The first structure 3100F may be a peripheral circuit structure including a decoder circuit 3110, a page buffer circuit 3120, and a logic circuit 3130. The second structure 3100S may be a memory cell structure including bitlines BL, a common source line CSL, wordlines WL, first and second upper gate lines UL1 and UL2, first and second lower gate lines LL1 and LL2, and memory cell strings CSTR between the bitlines BL and the common source line CSL.

In the second structure 3100S, each of the memory cell strings CSTR may include lower transistors LT1 and LT2 adjacent to the common source line CSL, upper transistors UT1 and UT2 adjacent to the bitlines BL, and a plurality of memory cell transistors MCT between the lower transistors LT1 and LT2 and the upper transistors UT1 and UT2. The number of the lower transistors LT1 and LT2 and the number of the upper transistors UT1 and UT2 may be varied in accordance with various examples of embodiments.

In the first structure 3100F, the decoder circuit 3110, the page buffer circuit 3120, and the logic circuit 3130 may correspond to the address decoder 520, the page buffer circuit 530, and the control circuit 560 in FIG. 3, respectively.

The common source line CSL, the first and second lower gate lines LL1 and LL2, the wordlines WL, and the first and second upper gate lines UL1 and UL2 may be electrically connected to the decoder circuit 3110 through first connection wirings 3115 extending to the second structure 3110S in the first structure 3100F. The bitlines BL may be electrically connected to the page buffer circuit 3120 through second connection wirings 3125 extending to the second structure 3100S in the first structure 3100F. The I/O pad 3101 may be electrically connected to the logic circuit 3130 through an I/O connection wiring 3135 extending to the second structure 3100S in the first structure 3100F.

The controller 3200 may include a processor 3210, a NAND controller 3220 and a host interface 3230. In some example embodiments, the electronic system 3000 may include a plurality of semiconductor devices 3100, and in this case, the controller 3200 may control the plurality of semiconductor devices 3100.

The processor 3210 may control operations of the electronic system 3000 including the controller 3200. The processor 3210 may be operated by firmware, and may control the NAND controller 3220 to access the semiconductor device 3100. The NAND controller 3220 may include a NAND interface 3221 for communicating with the semiconductor device 3100. Through the NAND interface 3221, control commands for controlling the semiconductor device 3100, data to be written in the memory cell transistors MCT of the semiconductor device 3100, data read from the memory cell transistors MCT of the semiconductor device 3100, etc., may be transferred. The host interface 3230 may provide communication between the electronic system 3000 and an outside host. When a control command is received from the outside host through the host interface 3230, the processor 3210 may control the semiconductor device 3100 in response to the control command.

FIG. 19 is a cross-sectional view of a memory device according to some example embodiments.

Referring to FIG. 19, a memory device (or nonvolatile memory device) 5000 may have a chip-to-chip (C2C) structure. At least one upper chip including a cell region and a lower chip including a peripheral circuit region PREG may be manufactured separately, and then, the at least one upper chip and the lower chip may be connected to each other by a bonding method to realize the C2C structure. For example, the bonding method may mean or may include a method of electrically or physically connecting a bonding metal pattern formed in an uppermost metal layer of the upper chip to a bonding metal pattern formed in an uppermost metal layer of the lower chip. For example, in cases in which the bonding metal patterns are formed of copper (Cu), the bonding method may be a Cu—Cu bonding method. Alternatively, the bonding metal patterns may be formed of aluminum (Al) or tungsten (W).

The memory device 5000 may include the at least one upper chip including the cell region. For example, as illustrated in FIG. 19, the memory device 5000 may include two upper chips. However, the number of the upper chips is not limited thereto. In the case in which the memory device 5000 includes the two upper chips, a first upper chip including a first cell region CREG1, a second upper chip including a second cell region CREG2 and the lower chip including the peripheral circuit region PREG may be manufactured separately, and then, the first upper chip, the second upper chip and the lower chip may be connected to each other by one or more bonding methods to manufacture the memory device 5000. The first upper chip may be turned over and then may be connected to the lower chip by a bonding method, and the second upper chip may also be turned over and then may be connected to the first upper chip by a bonding method. Hereinafter, upper and lower portions of each of the first and second upper chips will be defined based on before each of the first and second upper chips is turned over, or prior to the realization of the C2C structure. In other words, an upper portion of the lower chip may mean an upper portion defined based on a +Z-axis direction, and the upper portion of each of the first and second upper chips may mean an upper portion defined based on a −Z-axis direction in FIG. 19. However, the present disclosure is not limited thereto. In some example embodiments, one of the first upper chip and the second upper chip may be turned over and then may be connected to a corresponding chip by the bonding method.

Each of the peripheral circuit region PREG and the first and second cell regions CREG1 and CREG2 of the memory device 5000 may include an external pad bonding region PA, a wordline bonding region WLBA, and a bitline bonding region BLBA.

The peripheral circuit region PREG may include a first substrate 5210 and a plurality of circuit elements 5220a, 5220b and 5220c formed on the first substrate 5210. An interlayer insulating layer 5215 including one or more insulating layers may be provided on the plurality of circuit elements 5220a, 5220b and 5220c, and a plurality of metal lines electrically connected to the plurality of circuit elements 5220a, 5220b and 5220c may be provided in the interlayer insulating layer 5215. For example, the plurality of metal lines may include first metal lines 5230a, 5230b and 5230c connected to the plurality of circuit elements 5220a, 5220b and 5220c, and second metal lines 5240a, 5240b and 5240c formed on the first metal lines 5230a, 5230b and 5230c. The plurality of metal lines may be formed of at least one of various conductive materials. For example, the first metal lines 5230a, 5230b and 5230c may be formed of tungsten having a relatively high electrical resistivity, and the second metal lines 5240a, 5240b and 5240c may be formed of copper having a relatively low electrical resistivity. The present disclosure is not limited thereto.

The first metal lines 5230a, 5230b and 5230c and the second metal lines 5240a, 5240b and 5240c are illustrated and described in example embodiments. However, example embodiments are not limited thereto. In some example embodiments, at least one or more additional metal lines may further be formed on the second metal lines 5240a, 5240b and 5240c. In this case, the second metal lines 5240a, 5240b and 5240c may be formed of aluminum, and at least some of the additional metal lines formed on the second metal lines 5240a, 5240b and 5240c may be formed of copper having an electrical resistivity lower than that of aluminum of the second metal lines 5240a, 5240b and 5240c.

The interlayer insulating layer 5215 may be on the first substrate 5210 and may include an insulating material such as silicon oxide and/or silicon nitride.

Each of the first and second cell regions CREG1 and CREG2 may include at least one memory block. The first cell region CREG1 may include a second substrate 5310 and a common source line 5320. A plurality of wordlines 5330 (e.g., wordlines 5331 to 5338) may be stacked on the second substrate 5310 in a direction (i.e., the Z-axis direction) perpendicular to a top surface of the second substrate 5310. String selection lines and a ground selection line may be on and under the wordlines 5330, and the plurality of wordlines 5330 may be between the string selection lines and the ground selection line. Likewise, the second cell region CREG2 may include a third substrate 5410 and a common source line 5420, and a plurality of wordlines 5430 (e.g., wordlines 5431 to 5438) may be stacked on the third substrate 5410 in a direction (i.e., the Z-axis direction) perpendicular to a top surface of the third substrate 5410. Each of the second substrate 5310 and the third substrate 5410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CREG1 and CREG2.

In some example embodiments, as illustrated in a region ‘A1’, the channel structure CH may be provided in the bitline bonding region BLBA and may extend in the direction perpendicular to the top surface of the second substrate 5310 to penetrate or extend through the wordlines 5330, the string selection lines, and the ground selection line. The channel structure CH may include a data storage layer, a channel layer, and a filling insulation layer. The channel layer may be electrically connected to a first metal line 5350c and a second metal line 5360c in the bitline bonding region BLBA. For example, the second metal line 5360c may be a bitline and may be connected to the channel structure CH through the first metal line 5350c. The bitline 5360c may extend in a first direction (e.g., a Y-axis direction) parallel to the top surface of the second substrate 5310.

In some example embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 5310 to penetrate or extend through the common source line 5320 and lower wordlines 5331 and 5332. The lower channel LCH may include a data storage layer, a channel layer, and a filling insulation layer and may be connected to the upper channel UCH. The upper channel UCH may penetrate or extend through upper wordlines 5333 to 5338. The upper channel UCH may include a data storage layer, a channel layer, and a filling insulation layer, and the channel layer of the upper channel UCH may be electrically connected to the first metal line 5350c and the second metal line 5360c. As a length of a channel increases, due to characteristics of manufacturing processes, it may be difficult to form a channel having a substantially uniform width. The memory device 5000 according to some example embodiments may include a channel having improved width uniformity due to the lower channel LCH and the upper channel UCH which may be formed by processes performed sequentially.

In the case in which the channel structure CH includes the lower channel LCH and the upper channel UCH as illustrated in the region ‘A2’, a wordline located near to a boundary between the lower channel LCH and the upper channel UCH may be a dummy wordline. For example, the wordlines 5332 and 5333 adjacent to the boundary between the lower channel LCH and the upper channel UCH may be the dummy wordlines. In this case, data may not be stored in memory cells connected to the dummy wordline. Alternatively, the number of pages corresponding to the memory cells connected to the dummy wordline may be less than the number of pages corresponding to the memory cells connected to a general wordline. A level of a voltage applied to the dummy wordline may be different from a level of a voltage applied to the general wordline, and thus it may be possible to reduce an influence of a non-uniform channel width between the lower and upper channels LCH and UCH on an operation of the memory device.

In some example embodiments, the number of the lower wordlines 5331 and 5332 penetrated by the lower channel LCH may be less than the number of the upper wordlines 5333 to 5338 penetrated by the upper channel UCH in the region ‘A2’. However, example embodiments are not limited thereto. In some example embodiments, the number of the lower wordlines penetrated by the lower channel LCH may be equal to or more than the number of the upper wordlines penetrated by the upper channel UCH. In addition, structural features and connection relation of the channel structure CH in the second cell region CREG2 may be substantially the same as those of the channel structure CH in the first cell region CREG1, and duplicative description thereof is omitted here in the interest of brevity.

In the bitline bonding region BLBA, a first through-electrode THV1 may be provided in the first cell region CREG1, and a second through-electrode THV2 may be provided in the second cell region CREG2. As illustrated in FIG. 19, the first through-electrode THV1 may penetrate or extend through the common source line 5320 and the plurality of wordlines 5330. In some example embodiments, the first through-electrode THV1 may further penetrate the second substrate 5310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some example embodiments, the first through-electrode THV1 and the second through-electrode THV2 may be electrically connected to each other through a first through-metal pattern 5372d and a second through-metal pattern 5472d. The first through-metal pattern 5372d may be formed at a bottom end of the first upper chip including the first cell region CREG1, and the second through-metal pattern 5472d may be formed at a top end of the second upper chip including the second cell region CREG2. The first through-electrode THV1 may be electrically connected to the first metal line 5350c and the second metal line 5360c. A lower via 5371d may be formed between the first through-electrode THV1 and the first through-metal pattern 5372d, and an upper via 5471d may be formed between the second through-electrode THV2 and the second through-metal pattern 5472d. The first through-metal pattern 5372d and the second through-metal pattern 5472d may be connected to each other by a bonding method.

In addition, in the bitline bonding region BLBA, an upper metal pattern 5252 may be formed in an uppermost metal layer of the peripheral circuit region PREG, and an upper metal pattern 5392 having the same shape as the upper metal pattern 5252 may be formed in an uppermost metal layer of the first cell region CREG1. The upper metal pattern 5392 of the first cell region CREG1 and the upper metal pattern 5252 of the peripheral circuit region PREG may be electrically connected to each other by a bonding method. In the bitline bonding region BLBA, the bitline 5360c may be electrically connected to a page buffer included in the peripheral circuit region PREG. For example, some of the circuit elements 5220c of the peripheral circuit region PREG may constitute the page buffer, and the bitline 5360c may be electrically connected to the circuit elements 5220c constituting the page buffer through an upper bonding metal pattern 5370c of the first cell region CREG1 and an upper bonding metal pattern 5270c of the peripheral circuit region PREG.

Referring still to FIG. 19, in the wordline bonding region WLBA, the wordlines 5330 of the first cell region CREG1 may extend in a second direction (e.g., an X-axis direction) parallel to the top surface of the second substrate 5310 and may be connected to a plurality of cell contact plugs 5340 (e.g., cell contact plugs 5341 to 5347). First metal lines 5350b and second metal lines 5360b may be sequentially connected onto the cell contact plugs 5340 connected to the wordlines 5330. In the wordline bonding region WLBA, the cell contact plugs 5340 may be connected to the peripheral circuit region PREG through upper bonding metal patterns 5370b of the first cell region CREG1 and upper bonding metal patterns 5270b of the peripheral circuit region PREG.

The cell contact plugs 5340 may be electrically connected to a row decoder included in the peripheral circuit region PREG. For example, some of the circuit elements 5220b of the peripheral circuit region PREG may constitute the row decoder, and the cell contact plugs 5340 may be electrically connected to the circuit elements 5220b constituting the row decoder through the upper bonding metal patterns 5370b of the first cell region CREG1 and the upper bonding metal patterns 5270b of the peripheral circuit region PREG. In some example embodiments, an operating voltage of the circuit elements 5220b constituting the row decoder may be different from an operating voltage of the circuit elements 5220c constituting the page buffer. For example, the operating voltage of the circuit elements 5220c constituting the page buffer may be greater than the operating voltage of the circuit elements 5220b constituting the row decoder.

Likewise, in the wordline bonding region WLBA, the wordlines 5430 of the second cell region CREG2 may extend in the second direction (e.g., the X-axis direction) parallel to the top surface of the third substrate 5410 and may be connected to a plurality of cell contact plugs 5440 (e.g., cell contact plugs 5441 to 5447). The cell contact plugs 5440 may be connected to the peripheral circuit region PREG through an upper metal pattern of the second cell region CREG2 and lower and upper metal patterns and a cell contact plug 5348 of the first cell region CREG1.

In the wordline bonding region WLBA, the upper bonding metal patterns 5370b may be formed in the first cell region CREG1, and the upper bonding metal patterns 5270b may be formed in the peripheral circuit region PREG. The upper bonding metal patterns 5370b of the first cell region CREG1 and the upper bonding metal patterns 5270b of the peripheral circuit region PREG may be electrically connected to each other by the bonding method. The upper bonding metal patterns 5370b and the upper bonding metal patterns 5270b may be formed of aluminum, copper, or tungsten, as non-limiting examples.

In the external pad bonding region PA, a lower metal pattern 5371e may be formed in a lower portion of the first cell region CREG1, and an upper metal pattern 5472a may be formed in an upper portion of the second cell region CREG2. The lower metal pattern 5371e of the first cell region CREG1 and the upper metal pattern 5472a of the second cell region CREG2 may be connected to each other in the external pad bonding region PA by a bonding method. Likewise, an upper metal pattern 5372a may be formed in an upper portion of the first cell region CREG1, and an upper metal pattern 5272a may be formed in an upper portion of the peripheral circuit region PREG. The upper metal pattern 5372a of the first cell region CREG1 and the upper metal pattern 5272a of the peripheral circuit region PREG may be connected to each other by a bonding method.

Common source line contact plugs 5380 and 5480 may be in the external pad bonding region PA. The common source line contact plugs 5380 and 5480 may be formed of a conductive material such as a metal, a metal compound, and/or doped polysilicon. The common source line contact plug 5380 of the first cell region CREG1 may be electrically connected to the common source line 5320, and the common source line contact plug 5480 of the second cell region CREG2 may be electrically connected to the common source line 5420. A first metal line 5350a and a second metal line 5360a may be sequentially stacked on the common source line contact plug 5380 of the first cell region CREG1, and a first metal line 5450a and a second metal line 5460a may be sequentially stacked on the common source line contact plug 5480 of the second cell region CREG2.

Input/output pads 5205, 5405 and 5406 may be in the external pad bonding region PA. Referring to FIG. 19, a lower insulating layer 5201 may cover a bottom surface of the first substrate 5210, and a first input/output pad 5205 may be formed on the lower insulating layer 5201. The first input/output pad 5205 may be connected to at least one of a plurality of the circuit elements 5220a in the peripheral circuit region PREG through a first input/output contact plug 5203 and may be separated from the first substrate 5210 by the lower insulating layer 5201. In addition, a side insulating layer may be between the first input/output contact plug 5203 and the first substrate 5210 to electrically isolate the first input/output contact plug 5203 from the first substrate 5210.

An upper insulating layer 5401 covering a top surface of the third substrate 5410 may be formed on the third substrate 5410. A second input/output pad 5405 and/or a third input/output pad 5406 may be on the upper insulating layer 5401. The second input/output pad 5405 may be connected to at least one of the plurality of circuit elements 5220a in the peripheral circuit region PREG through second input/output contact plugs 5403 and 5303, and the third input/output pad 5406 may be connected to at least one of the plurality of circuit elements 5220a disposed in the peripheral circuit region PREG through third input/output contact plugs 5404 and 5304.

In some example embodiments, the third substrate 5410 may not be provided in a region in which the input/output contact plug is arranged. For example, as illustrated in a region ‘B’, the third input/output contact plug 5404 may be separated from the third substrate 5410 in a direction parallel to the top surface of the third substrate 5410 and may penetrate or extend through an interlayer insulating layer 5415 of the second cell region CREG2 so as to be connected to the third input/output pad 5406. In this case, the third input/output contact plug 5404 may be formed by at least one of various processes.

In some example embodiments, as illustrated in a region ‘B1’, the third input/output contact plug 5404 may extend in a third direction (e.g., the Z-axis direction), and a diameter of the third input/output contact plug 5404 may become progressively greater toward the upper insulating layer 5401. In other words, a diameter of the channel structure CH described in the region ‘A1’ may become progressively less toward the upper insulating layer 5401, but the diameter of the third input/output contact plug 5404 may become progressively greater toward the upper insulating layer 5401. For example, the third input/output contact plug 5404 may be formed after the second cell region CREG2 and the first cell region CREG1 are bonded to each other by the bonding method.

In some example embodiments, as illustrated in a region ‘B2’, the third input/output contact plug 5404 may extend in the third direction (e.g., the Z-axis direction), and a diameter of the third input/output contact plug 5404 may become progressively less toward the upper insulating layer 5401. In other words, like the channel structure CH, the diameter of the third input/output contact plug 5404 may become progressively less toward the upper insulating layer 5401. For example, the third input/output contact plug 5404 may be formed together with the cell contact plugs 5440 before the second cell region CREG2 and the first cell region CREG1 are bonded to each other.

In some example embodiments, the input/output contact plug may overlap with the third substrate 5410. For example, as illustrated in a region ‘C’, the second input/output contact plug 5403 may penetrate or extend through the interlayer insulating layer 5415 of the second cell region CREG2 in the third direction (e.g., the Z-axis direction) and may be electrically connected to the second input/output pad 5405 through the third substrate 5410. In this case, a connection structure of the second input/output contact plug 5403 and the second input/output pad 5405 may be realized by various methods.

In some example embodiments, as illustrated in a region ‘C1’, an opening 5408 may be formed to penetrate or extend through the third substrate 5410, and the second input/output contact plug 5403 may be connected directly to the second input/output pad 5405 through the opening 5408 formed in the third substrate 5410. In this case, as illustrated in the region ‘C1’, a diameter of the second input/output contact plug 5403 may become progressively greater toward the second input/output pad 5405. However, example embodiments are not limited thereto, and in some example embodiments, the diameter of the second input/output contact plug 5403 may become progressively less toward the second input/output pad 5405.

In some example embodiments, as illustrated in a region ‘C2’, the opening 5408 penetrating or extending through the third substrate 5410 may be formed, and a contact 5407 may be formed in the opening 5408. An end of the contact 5407 may be connected to the second input/output pad 5405, and another end of the contact 5407 may be connected to the second input/output contact plug 5403. Thus, the second input/output contact plug 5403 may be electrically connected to the second input/output pad 5405 through the contact 5407 in the opening 5408. In this case, as illustrated in the region ‘C2’, a diameter of the contact 5407 may become progressively greater toward the second input/output pad 5405, and a diameter of the second input/output contact plug 5403 may become progressively less toward the second input/output pad 5405. For example, the second input/output contact plug 5403 may be formed together with the cell contact plugs 5440 before the second cell region CREG2 and the first cell region CREG1 are bonded to each other, and the contact 5407 may be formed after the second cell region CREG2 and the first cell region CREG1 are bonded to each other.

In some example embodiments illustrated in a region ‘C3’, a stopper 5409 may further be formed on a bottom end of the opening 5408 of the third substrate 5410, as compared with the embodiments of the region ‘C2’. The stopper 5409 may be a metal line formed in the same layer as the common source line 5420. Alternatively, the stopper 5409 may be a metal line formed in the same layer as at least one of the wordlines 5430. The second input/output contact plug 5403 may be electrically connected to the second input/output pad 5405 through the contact 5407 and the stopper 5409.

Like the second and third input/output contact plugs 5403 and 5404 of the second cell region CREG2, a diameter of each of the second and third input/output contact plugs 5303 and 5304 of the first cell region CREG1 may become progressively less toward the lower metal pattern 5371e or may become progressively greater toward the lower metal pattern 5371e.

In some example embodiments, a slit 5411 may be formed in the third substrate 5410. For example, the slit 5411 may be formed at a certain position of the external pad bonding region PA. For example, as illustrated in a region ‘D’, the slit 5411 may be located between the second input/output pad 5405 and the cell contact plugs 5440 when viewed in a plan view. In some embodiments, the second input/output pad 5405 may be located between the slit 5411 and the cell contact plugs 5440 when viewed in a plan view.

In some example embodiments, as illustrated in a region ‘D1’, the slit 5411 may be formed to penetrate or extend through the third substrate 5410. For example, the slit 5411 may be used to prevent the third substrate 5410 from being finely cracked when the opening 5408 is formed. However, the present disclosure is not limited thereto, and in some example embodiments, the slit 5411 may be formed to have a depth ranging from about 60% to about 70% of a thickness of the third substrate 5410.

In some example embodiments, as illustrated in a region ‘D2’, a conductive material 5412 may be formed in the slit 5411. For example, the conductive material 5412 may be used to discharge a leakage current that may occur in driving of the circuit elements in the external pad bonding region PA to the outside. In this case, the conductive material 5412 may be connected to an external ground line.

In some example embodiments, as illustrated in a region ‘D3’, an insulating material 5413 may be formed in the slit 5411. For example, the insulating material 5413 may be used to electrically isolate the second input/output pad 5405 and the second input/output contact plug 5403 arranged in the external pad bonding region PA from the wordline bonding region WLBA. Since the insulating material 5413 is formed in the slit 5411, it is possible to prevent a voltage provided through the second input/output pad 5405 from affecting a metal layer on the third substrate 5410 in the wordline bonding region WLBA.

In some example embodiments, the first to third input/output pads 5205, 5405 and 5406 may be selectively formed. For example, the memory device 5000 may be realized to include only the first input/output pad 5205 on the first substrate 5210, to include only the second input/output pad 5405 on the third substrate 5410, or to include only the third input/output pad 5406 on the upper insulating layer 5401.

In some example embodiments, at least one of the second substrate 5310 of the first cell region CREG1 or the third substrate 5410 of the second cell region CREG2 may be used as a sacrificial substrate and may be completely or partially removed before or after a bonding process. An additional layer may be stacked after the removal of the substrate. For example, the second substrate 5310 of the first cell region CREG1 may be removed before or after the bonding process of the peripheral circuit region PREG and the first cell region CREG1, and then, an insulating layer covering a top surface of the common source line 5320 or a conductive layer for connection may be formed. Likewise, the third substrate 5410 of the second cell region CREG2 may be removed before or after the bonding process of the first cell region CREG1 and the second cell region CREG2, and then, the upper insulating layer 5401 covering a top surface of the common source line 5420 or a conductive layer for connection may be formed.

FIG. 20 is a diagram illustrating a manufacturing process of a memory device according to some example embodiments.

Referring to FIG. 20, respective integrated circuits may be formed on a first wafer WF1 and a second wafer WF2. The memory cell array may be formed in the first wafer WF1, and the peripheral circuits may be formed in the second wafer WF2.

After the various integrated circuits have been respectively formed on the first and second wafers WF1 and WF2, the first wafer WF1 and the second wafer WF2 may be bonded together. The bonded wafers WF1 and WF2 may then be cut (or divided) into separate chips, in which each chip corresponds to a semiconductor device such as, for example, a memory device 6000, including a first semiconductor die SD1 and a second semiconductor die SD2 that are stacked vertically (e.g., the first semiconductor die SD1 is stacked on the second semiconductor die SD2, etc.). Each cut portion of the first wafer WF1 may correspond to the first semiconductor die SD1, and each cut portion of the second wafer WF2 may correspond to the second semiconductor die SD2. For example, the memory device 5000 of FIG. 19 may be manufactured based on the manufacturing process of FIG. 20.

The example embodiments may be applied to various electronic devices and systems that include nonvolatile memory devices and memory packages. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, and so on.

The foregoing is illustrative of example embodiments and is not to be construed as limiting thereof. Although some example embodiments have been described, those skilled in the art will readily appreciate that many modifications are possible in the example embodiments without materially departing from the teachings and advantages of the present disclosure. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A nonvolatile memory device comprising:
a first semiconductor layer including a plurality of wordlines that extend in a first direction and a plurality of bitlines that extend in a second direction that intersects the first direction, the first semiconductor layer further including:
a first substrate; and
a memory cell array on the first substrate and connected to the plurality of wordlines and the plurality of bitlines;
a second semiconductor layer arranged with respect to the first semiconductor layer in a third direction perpendicular to both the first direction and the second direction, the second semiconductor layer including:
a second substrate; and
a peripheral circuit on the second substrate and configured to control the memory cell array; and
a plurality of pass transistors connected to the plurality of wordlines and configured to control an electrical connection between the memory cell array and the peripheral circuit,
wherein a first part of the plurality of pass transistors are in the first semiconductor layer, and a second part of the plurality of pass transistors are in the second semiconductor layer.

2. The nonvolatile memory device of claim 1,
wherein the plurality of wordlines include:
first wordlines stacked on the first substrate in the third direction; and
second wordlines stacked on the first wordlines in the third direction,
wherein the plurality of pass transistors include:
first pass transistors connected to the first wordlines; and
second pass transistors connected to the second wordlines,
wherein the first pass transistors are in the first substrate of the first semiconductor layer, and the second pass transistors are in the second substrate of the second semiconductor layer.

3. The nonvolatile memory device of claim 2,
wherein the memory cell array includes:
a core region including a plurality of memory cells; and
an extension region adjacent to a first side of the core region and including a plurality of wordline contacts for electrical connections between the plurality of wordlines and the plurality of pass transistors,
wherein the plurality of wordline contacts includes:
first wordline contacts configured to electrically connect the first wordlines with the first pass transistors; and
second wordline contacts configured to electrically connect the second wordlines with the second pass transistors.

4. The nonvolatile memory device of claim 3, wherein the first wordline contacts and the second wordline contacts are aligned with each other in the third direction.

5. The nonvolatile memory device of claim 3,
wherein the extension region further includes:
a plurality of step zones having a step shape in a cross-sectional view with respect to the plurality of wordlines; and
at least one flat zone having a flat shape in the cross-sectional view with respect to the plurality of wordlines,
wherein the plurality of wordline contacts are in the plurality of step zones.

6. The nonvolatile memory device of claim 2, further comprising:
a plurality of drivers configured to control switching operations of the plurality of pass transistors,
wherein the plurality of drivers include:
first drivers configured to control switching operations of the first pass transistors; and
second drivers configured to control switching operations of the second pass transistors,
wherein the first drivers are in the first substrate of the first semiconductor layer adjacent to the first pass transistors, and the second drivers are in the second substrate of the second semiconductor layer adjacent to the second pass transistors.

7. The nonvolatile memory device of claim 2,
wherein the memory cell array includes:
a plurality of channel holes extending in the third direction to form the plurality of wordlines and a plurality of memory cells,
wherein each of the plurality of channel holes includes:
a first sub-channel hole and a second sub-channel hole sequentially stacked on the first substrate in the third direction,
wherein the first wordlines correspond to the first sub-channel hole, and the second wordlines correspond to the second sub-channel hole.

8. (canceled)

9. The nonvolatile memory device of claim 1, wherein:
wherein the plurality of wordlines include:
first wordlines stacked on the first substrate in the third direction; and
second wordlines stacked on the first wordlines in the third direction, wherein the first wordlines are divided into a first wordline group and a second wordline group,
wherein the plurality of pass transistors include:
a first pass transistor group connected to the first wordline group; and
a second pass transistor group connected to the second wordline group,
wherein the first pass transistor group is in the first substrate of the first semiconductor layer, and the second pass transistor group are in the second substrate of the second semiconductor layer.

10. The nonvolatile memory device of claim 9, wherein, among the first wordlines, one of odd-numbered wordlines and even-numbered wordlines is set as the first wordline group, and other of the odd-numbered wordlines and the even-numbered wordlines is set as the second wordline group.

11. The nonvolatile memory device of claim 9, wherein, among the first wordlines, K first-first wordlines sequentially stacked in the third direction are set as the first wordline group, and K first-second wordlines adjacent to the K first-first wordlines and sequentially stacked in the third direction are set as the second wordline group, where K is a positive integer greater than or equal to two.

12. The nonvolatile memory device of claim 9,
wherein the second wordlines are divided into a third wordline group and a fourth wordline group,
wherein the plurality of pass transistors further include:
a third pass transistor group connected to the third wordline group; and
a fourth pass transistor group connected to the fourth wordline group,
wherein the third pass transistor group is in the first substrate of the first semiconductor layer, and the fourth pass transistor group are in the second substrate of the second semiconductor layer.

13. The nonvolatile memory device of claim 12,
wherein, in the first substrate, the first pass transistor group and the third pass transistor group are alternately arranged along the first direction,
wherein, in the second substrate, the second pass transistor group and the fourth pass transistor group are alternately arranged along the first direction.

14. The nonvolatile memory device of claim 12,
wherein the memory cell array includes:
a core region including a plurality of memory cells; and
an extension region adjacent to a first side of the core region and including a plurality of wordline contacts for electrical connections between the plurality of wordlines and the plurality of pass transistors,
wherein the plurality of wordline contacts includes:
a first wordline contact group configured to electrically connect the first wordline group with the first pass transistor group;
a second wordline contact group configured to electrically connect the second wordline group with the second pass transistor group;
a third wordline contact group configured to electrically connect the third wordline group with the third pass transistor group; and
a fourth wordline contact group configured to electrically connect the fourth wordline group with the fourth pass transistor group.

15. The nonvolatile memory device of claim 14, wherein the first wordline contact group, the second wordline contact group, the third wordline contact group and the fourth wordline contact group are alternately arranged along the first direction.

16. The nonvolatile memory device of claim 14,
wherein the extension region further includes:
first step zones having a step shape in a cross-sectional view with respect to the first wordlines; and
second step zones having the step shape in a cross-sectional view with respect to the second wordlines,
wherein the first wordline contact group and the second wordline contact group are in the first step zones, and the third wordline contact group and the fourth wordline contact group are in the second step zones.

17. (canceled)

18. The nonvolatile memory device of claim 16,
wherein at least one first flat zone having a flat shape in the cross-sectional view with respect to the first wordlines is omitted between the first step zones,
wherein at least one second flat zone having the flat shape in the cross-sectional view with respect to the second wordlines is omitted between the second step zones.

19. The nonvolatile memory device of claim 1, wherein the first part of the plurality of pass transistors in the first semiconductor layer and the second part of the plurality of pass transistors in the second semiconductor layer have different widths or different lengths.

20. The nonvolatile memory device of claim 1, further comprising:
a third semiconductor layer disposed with respect to the first semiconductor layer in the third direction, the third semiconductor layer including:
a third substrate; and
a second peripheral circuit on the third substrate and configured to control the memory cell array,
wherein a third part of the plurality of pass transistors are in the third semiconductor layer.

21. A nonvolatile memory device comprising:
a first semiconductor layer including a plurality of wordlines that extend in a first direction and a plurality of bitlines that extend in a second direction that crosses the first direction, the first semiconductor layer further including:
a first substrate; and
a memory cell array on the first substrate and connected to the plurality of wordlines and the plurality of bitlines;
a second semiconductor layer arranged with respect to the first semiconductor layer in a third direction perpendicular to both the first direction and the second direction, the second semiconductor layer including:
a second substrate; and
a first peripheral circuit on the second substrate and configured to control the memory cell array;
a third semiconductor layer arranged with respect to the first semiconductor layer in the third direction, the third semiconductor layer including:
a third substrate; and
a second peripheral circuit on the third substrate and configured to control the memory cell array; and
a plurality of pass transistors connected to the plurality of wordlines and configured to control an electrical connection between the memory cell array and the first and second peripheral circuits,
wherein a first part of the plurality of pass transistors are in the second semiconductor layer, and a second part of the plurality of pass transistors are in the third semiconductor layer.

22. (canceled)

23. A nonvolatile memory device comprising:
a first semiconductor layer including a plurality of wordlines that extend in a first direction and a plurality of bitlines that extend in a second direction that crosses the first direction, the first semiconductor layer further including:
a first substrate; and
a memory cell array on the first substrate and connected to the plurality of wordlines and the plurality of bitlines;
a second semiconductor layer arranged with respect to the first semiconductor layer in a third direction perpendicular to both the first direction and the second direction, the second semiconductor layer including:
a second substrate; and
a peripheral circuit on the second substrate and configured to control the memory cell array;
a plurality of pass transistors connected to the plurality of wordlines and configured to control an electrical connection between the memory cell array and the peripheral circuit; and
a plurality of drivers configured to control switching operations of the plurality of pass transistors,
wherein the memory cell array includes:
a core region including a plurality of memory cells; and
an extension region adjacent to a first side of the core region and including a plurality of wordline contacts for electrical connections between the plurality of wordlines and the plurality of pass transistors,
wherein the plurality of wordlines include first wordlines and second wordlines,
wherein the plurality of pass transistors include first pass transistors connected to the first wordlines, and second pass transistors connected to the second wordlines,
wherein the plurality of drivers include first drivers configured to control switching operations of the first pass transistors, and second drivers configured to control switching operations of the second pass transistors,
wherein the plurality of wordline contacts includes first wordline contacts configured to electrically connect the first wordlines with the first pass transistors, and second wordline contacts configured to electrically connect the second wordlines with the second pass transistors,
wherein the first pass transistors and the first drivers are in the first substrate of the first semiconductor layer, and the second pass transistors and the second drivers are in the second substrate of the second semiconductor layer,
wherein the first wordline contacts and the second wordline contacts are in the extension region of the first semiconductor layer.
